(19) United States
(12) Patent Application Publication
(10) Pub. No.: US 2026/0079391 A1
(43) Pub. Date: Mar. 19, 2026

(54) IMPRINT DEVICE AND IMPRINT METHOD

(71) Applicant: Kioxia Corporation, Tokyo (JP)

(72) Inventors: Anupam MITRA, Yokkaichi Mie (JP); Masaki MITSUYASU, Kuwana Mie (JP); Kazuya FUKUHARA, Yokkaichi Mie (JP); Ryo OGAWA, Mie Mie (JP); Norikazu TAKEUCHI, Yokkaichi Mie (JP)

(21) Appl. No.: 19/070,419

(22) Filed: Mar. 4, 2025

(30) Foreign Application Priority Data
Sep. 18, 2024 (JP) 2024-160764

(51) Int. Cl. G03F 7/00; B29C 43/14; B29L 31/34; H01L 21/027

(52) U.S. Cl. CPC G03F 7/0002; B29C 43/14; H10P 76/20; B29L 2031/3406

(57) ABSTRACT

An imprint device includes a template having a pattern to be transferred to a resin material disposed on a processing substrate or a dummy substrate, and a control unit that performs first imprint processing in which the template is pressed against an uncured first resin material disposed on one shot region of the processing substrate to transfer the pattern to the first resin material, and second imprint processing in which the template is pressed against an uncured second resin material disposed on the dummy substrate. The control unit performs the second imprint processing after the first imprint processing performed on a first shot region and before the first imprint processing performed on a second shot region, wherein the first imprint processing is to be performed on the first shot region and the second shot region in successive order.

### CROSS-REFERENCE TO RELATED APPLICATION(S)

This application is based upon and claims the benefit of priority from Japanese Patent Application No. 2024-160764, filed Sep. 18, 2024, the entire contents of which are incorporated herein by reference.

### FIELD

Embodiments described herein relate generally to an imprint device and an imprint method.

### BACKGROUND

A manufacturing process for a semiconductor device may include imprint processing. In the imprint processing, a pattern of a template is transferred to a resist material on a shot region of a substrate. At an outer periphery of the substrate, a part of the shot region may be missing, and such a shot region is referred to as a missing shot. After the imprint processing of the missing shot, a residue of the resist material may adhere to the template, causing defects during the next imprint processing.

### BRIEF DESCRIPTION OF THE DRAWINGS

FIG. 1 is a schematic diagram showing an example of a configuration of an imprint device according to a first embodiment.

FIGS. 2A and 2B are a schematic diagram showing an example of a configuration of a wafer processed by the imprint device according to the first embodiment.

FIGS. 3A to 3C, 4A to 4C, and 5A to 5D are cross-sectional views showing a portion of a procedure of a method of manufacturing a semiconductor device according to the first embodiment.

FIGS. 6A to 6D, 7A to 7D, and 8A to 8B are schematic top views showing a portion of a procedure of an imprint method using the imprint device according to the first embodiment.

FIG. 9 is a top view showing an example of a wafer stage of an imprint device according to a first modification example of the first embodiment.

FIGS. 10A to 10I are top views sequentially showing a portion of a procedure of imprint processing using an imprint device according to a second modification example of the first embodiment.

FIG. 11 is a flow diagram sequentially showing a portion of the procedure of the imprint processing using the imprint device according to the second modification example of the first embodiment.

FIG. 12 is a schematic diagram showing an example of a configuration of an imprint device according to a second embodiment.

FIGS. 13A to 13C and 14A to 14C are schematic top views showing a portion of a procedure of an imprint method using the imprint device according to the second embodiment.

FIG. 15 is a schematic diagram showing an example of a configuration of an imprint device according to a third embodiment.

FIG. 16 is a schematic top view sequentially showing a portion of a procedure of an imprint method using the imprint device according to the third embodiment.

FIGS. 17A to 17C are schematic diagrams showing an example of a configuration of an imprint device according to a fourth embodiment.

FIGS. 18A and 18B, 19A and 19B, 20A and 20B, and 21A and 21B are schematic top views showing an example of the operation of a light shielding plate provided in the imprint device according to the fourth embodiment.

FIGS. 22A to 22B, 23A to 23B, and 24 are cross-sectional views showing a portion of a procedure of a method of manufacturing a semiconductor device according to the fourth embodiment.

### DETAILED DESCRIPTION

Embodiments provide an imprint device and an imprint method which are capable of curbing defects in imprint processing after missing shot processing.

In general, according to one embodiment, an imprint device is an imprint device that performs imprint processing on a processing substrate having a plurality of shot regions, which include a first shot region and a second shot region, uses a template having a pattern to be transferred to a resin material disposed on the processing substrate or a dummy substrate, and includes a control unit that performs first imprint processing in which the template is pressed against an uncured first resin material disposed on one shot region among the plurality of shot regions of the processing substrate to transfer the pattern to the first resin material, and second imprint processing in which the template is pressed against an uncured second resin material disposed on the dummy substrate, wherein the control unit performs the second imprint processing after the first imprint processing on the first shot region and before the first imprint processing on the second shot region.

In the following, embodiments of the present disclosure will be described in detail with reference to the drawings. The present disclosure is not limited to the following embodiments. Components in the following embodiments include those that can be easily attained or realized by a person skilled in the art or that are substantially the same.

### First Embodiment

In the following, a first embodiment will be described in detail with reference to the drawings.

### Example of Configuration of Imprint Device

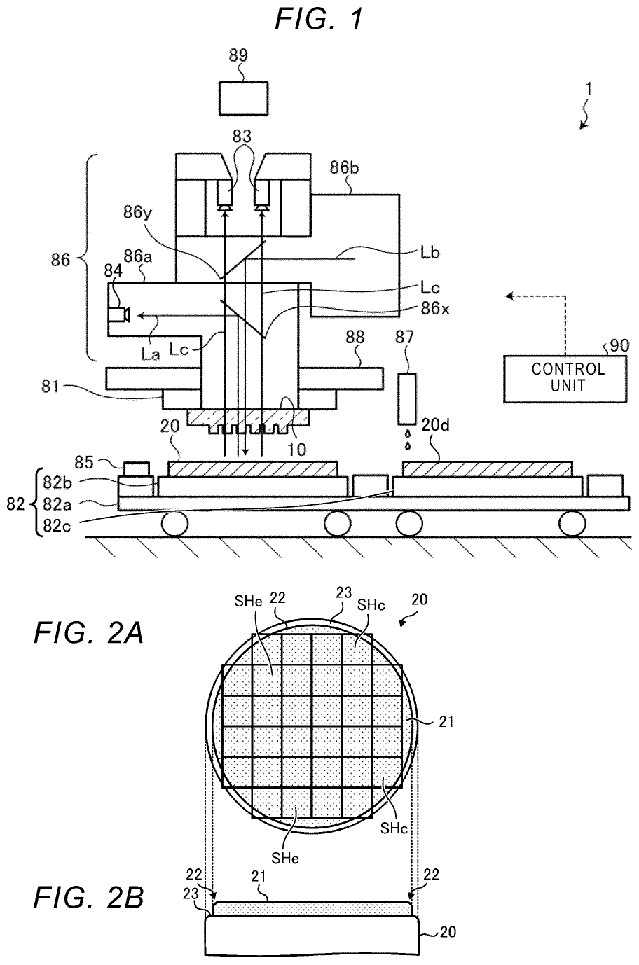

FIG. 1 is a schematic diagram showing an example of a configuration of an imprint device 1 according to a first embodiment.

As shown in FIG. 1, the imprint device 1 includes a template stage 81, a wafer stage 82, imaging elements 83 and 84, a reference mark 85, an alignment unit 86, a droplet dropping device 87, a stage base 88, a light source 89, and a control unit 90.

A template 10 that transfers a pattern to a resist on a wafer 20 can be attached to the imprint device 1. The wafer 20 undergoes various processes including processes using the imprint device 1, during manufacturing of a semiconductor device. Such a wafer 20 can be a semiconductor substrate, an insulating substrate, a conductive substrate, or the like.

The wafer stage 82 includes wafer chucks 82b and 82c, and a main body 82a. The wafer 20 to be subjected to imprint processing is placed on the wafer chuck 82b. A dummy wafer 20d is placed on the wafer chuck 82c. The dummy wafer 20d is a wafer that does not become a semiconductor device and is used only during the imprint processing for the wafer 20, and may be a semiconductor substrate, an insulating substrate, a conductive substrate, or the like similar to the wafer 20.

The wafer chucks 82b and 82c are disposed adjacent to each other on the main body 82a of the wafer stage 82, and are configured as suction chucks that chuck the wafer 20 and the dummy wafer 20d by evacuation so that each is attached at a predetermined position on the main body 82a.

The reference mark 85 is provided on the wafer stage 82. The reference mark 85 is used for alignment when loading the wafer 20 or the dummy wafer 20d onto the wafer stage 82.

The wafer stage 82 has the wafer 20 and the dummy wafer 20d placed thereon and moves in a parallel plane (horizontal plane). The wafer stage 82 moves the wafer 20 or the dummy wafer 20d below the droplet dropping device 87 when dropping a resist onto the wafer 20 or the dummy wafer 20d, and the wafer stage 82 moves the wafer 20 or the dummy wafer 20d below the template 10 when performing imprint processing on the wafer 20 or the dummy wafer 20d.

The stage base 88 supports the template 10 using the template stage 81 and presses the pattern of the template 10 against the resist on the wafer 20 or the dummy wafer 20d by moving up and down (vertically).

The alignment unit 86 equipped with a plurality of imaging elements 83 is provided on the stage base 88. The alignment unit 86 detects the position of the wafer 20 and the position of the template 10 on the basis of the alignment marks provided on the wafer 20 and the template 10, respectively.

The alignment unit 86 includes a detection system 86a and an illumination system 86b. The illumination system 86b illuminates the wafer 20 and the template 10 with light to make the alignment marks formed thereon visible. The detection system 86a detects images of the alignment marks and aligns the wafer 20 and the template 10 by aligning their positions.

The detection system 86a and the illumination system 86b include mirrors 86x and 86y such as dichroic mirrors as imaging units. The mirrors 86x and 86y form images of the alignment marks and the like from the wafer 20 and the template 10 using light from the illumination system 86b.

Specifically, light Lb from the illumination system 86b is reflected by the mirror 86y downward where the wafer 20 and the like are disposed. In addition, light La from the wafer 20 or the like is reflected by the mirror 86x toward the detection system 86a. Further, a portion of light Lc from the wafer 20 or the like passes through the mirrors 86x and 86y and travels toward the imaging element 83 disposed above.

The imaging element 83 captures a portion of the light Lc as an image including alignment marks and the like. The image captured by the imaging element 83 is analyzed by the control unit 90 in order to align the wafer 20 with the template 10.

Meanwhile, the light La reflected by the mirror 86x toward the detection system 86a advances toward the imaging element 84 provided in the detection system 86a.

The imaging element 84 captures the light La reflected by the mirror 86x as an image including alignment marks and the like. The image captured by the imaging element 84 is analyzed by the control unit 90 in order to align the wafer 20 with the template 10.

The alignment marks and the like are also formed on the dummy wafer 20d, and thus the alignment between the dummy wafer 20d and the template 10 may be performed in the same procedure as the alignment between the wafer 20 and the template 10 described above.

The droplet dropping device 87 is a device that drops a resist onto the wafer 20 or onto the dummy wafer 20d by an inkjet method. An inkjet head of the droplet dropping device 87 has a plurality of fine holes that eject droplets of the resist, and by which the droplets of the resist are dropped onto a shot region on the wafer 20 or onto the dummy wafer 20d.

The light source 89 is a device that emits light such as ultraviolet light for curing the resist, and is provided above the stage base 88. The light source 89 emits light from above the template 10 while the template 10 is pressed against the resist.

The control unit 90 is, for example, a computer equipped with a hardware processor such as a central processor (CPU), a memory, and a hard disk drive (HDD). The control unit 90 controls the template stage 81, the wafer stage 82, the reference mark 85, the alignment unit 86 including the imaging elements 83 and 84, the droplet dropping device 87, the stage base 88, and the light source 89.

Next, an example of a configuration of the wafer 20 to be processed by the imprint device 1 will be described with reference to FIGS. 2A and 2B.

FIGS. 2A and 2B are a schematic diagram showing an example of a configuration of the wafer 20 to be processed by the imprint device 1 according to the first embodiment. More specifically, FIG. 2A is a top view of the wafer 20, and FIG. 2B is a cross-sectional view of the side of the wafer 20.

As shown in FIGS. 2A and 2B, the wafer 20 has a convex region 21 in which a plurality of layers are stacked, except for the outer periphery. Before the processing performed by the imprint device 1, the wafer 20 has already been subjected to, for example, a plurality of processes. The plurality of layers in the convex region 21 may include an insulating layer, a conductive layer, a semiconductor layer, and the like formed by these processes.

An edge region 23 is provided at the outer periphery of the wafer 20, the edge region 23 being formed by removing these layers. By removing some or all of the plurality of layers that form the convex region 21, the surface of the wafer 20, which is, for example, a silicon substrate, is exposed in the edge region 23. Thereby, the convex region 21 protrudes from the surface of the wafer 20, and the wafer 20 has a step 22 at a boundary between the convex region 21 and the edge region 23, the step 22 descending from the convex region 21 toward the edge region 23. The height of the step 22 is, for example, on the order of microns.

The step 22 of the wafer 20 surrounds the outer periphery of the wafer 20 in a circular shape going around the outer periphery. The convex region 21 defined from the edge region 23 by the step 22 has a substantially similar shape to the wafer 20, and is a circular region when viewed from the upper surface of the wafer 20.

In addition, the upper surface of the wafer 20 is partitioned into a plurality of shot regions SH (SHe, SHc) by the processes performed up to this point. The plurality of shot regions SH are arranged in a lattice pattern over almost the entire surface of the wafer 20. Of these shot regions SH, the shot regions SHe that are arranged in the region excluding the outer periphery of the wafer 20 each have, for example, a rectangular shape. Meanwhile, the shot region SHc that is disposed at the outer periphery of the wafer 20 is a missing shot that is not completely formed within the convex region 21.

These shot regions SH are regions that become processing units per one process in some processes including the imprint processing among the plurality of manufacturing processes for the semiconductor device. That is, for example, in the imprint processing to be described below, a process of transferring the pattern of the template 10 is performed for each shot region SH. In the final stage of the manufacturing process for the semiconductor device, one or a plurality of semiconductor chips are fragmented into individual pieces, where each piece corresponds to one of the shot regions SH, and one or more semiconductor devices are obtained.

### Method of Manufacturing Semiconductor Device

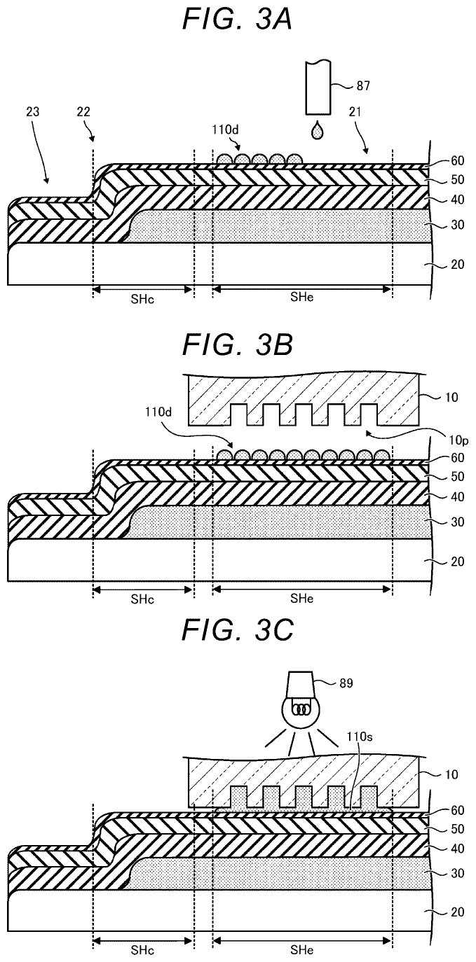

Next, a method of manufacturing the semiconductor device according to the first embodiment will be described with reference to FIGS. 3A to 3C, 4A to 4C and 5A to 5D.

FIGS. 3A to 3C, 4A to 4C and 5A to 5D are cross-sectional views sequentially showing a portion of a procedure of the method of manufacturing the semiconductor device according to the first embodiment. The manufacturing process for the semiconductor device according to the first embodiment includes imprint processing using the imprint device 1 described above.

When starting the imprint processing, the template 10, the wafer 20, and the dummy wafer 20d are transported into the imprint device 1. In addition, the template 10 is attached to the template stage 81, and the wafer 20 and the dummy wafer 20d are placed on the wafer chucks 82b and 82c of the wafer stage 82, respectively.

As shown in FIG. 3A, a plurality of layers 30 that have been removed from the edge region 23 to form a convex shape, a to-be-processed layer 40 that covers the plurality of layers 30, a spin on carbon (SOC) layer 50, and a spin on glass (SOG) layer 60 are formed, for example, on the entire surface of the wafer 20 transported into the imprint device 1 in this order from the wafer 20 side.

The to-be-processed layer 40 is a layer that is processed into a pattern transferred to the wafer 20 by the imprint processing, and is, for example, an insulating layer such as a silicon oxide layer. The SOC layer 50 is an organic layer that contains carbon as the main raw material. The SOG layer 60 is an inorganic layer such as a silicon oxide layer. Both the SOC layer 50 and the SOG layer 60 are formed, for example, by a spin coating method.

Each of these layers is formed in the convex region 21, the step 22, and the edge region 23 so as to follow the step 22 provided in the wafer 20 by removing the plurality of layers 30 from the edge region 23 of the wafer 20. Thereby, the step 22 is also formed in each of these layers, and the wafer 20 has the convex region 21 and the edge region 23 with the step 22 as the boundary.

In addition, as described above, the plurality of shot regions SH are provided on the wafer 20 on which these layers are formed. The imprint device 1 sequentially performs imprint processing to be described below on these shot regions SH.

First, the state of imprint processing performed on a shot region SHe having no missing portion among the plurality of shot regions SH is shown below.

Droplets 110d of a resist material or the like are dropped onto the shot region SHe to be processed by the droplet dropping device 87 of the imprint device 1. The droplets 110d of the resist material are, for example, a photocurable photoresist, and are dropped onto the wafer 20 in a liquid state before curing.

As shown in FIG. 3B and the like, when a target of imprint processing is a shot region SHe having no missing portion, a plurality of droplets 100d are distributed over the entire shot region SHe.

The template 10, which has been transported into the imprint device 1 and attached to the template stage 81, is disposed at a position that vertically faces the shot region SHe onto which a plurality of droplets 110d have been dropped.

The template 10 is attached to the template stage 81 with a surface having a predetermined pattern 10p facing the wafer 20. The pattern 10p provided on the template 10 can be appropriately changed depending on a pattern desired to be formed on the to-be-processed layer 40, such as a line and space pattern, a dot pattern, or a hole pattern.

In a state where the template 10 is spaced from the wafer 20 at a predetermined distance so as to face the wafer 20, rough alignment is performed while observing the alignment marks on the template 10 and the wafer 20, for example, by the imaging element 83 of the imprint device 1.

Rough alignment is processing in which the template 10 and the wafer 20 are roughly aligned so that the alignment marks thereon overlap each other while they are spaced apart from each other.

As shown in FIG. 3C, after the rough alignment ends, the pattern 10p of the template 10 is brought into contact with the plurality of droplets 110d on the shot region SHe. At this time, the template 10 is held above the wafer 20 while leaving a small gap between the template 10 and the SOG layer 60, which is the uppermost layer of the wafer 20.

Thereafter, the template 10 is maintained at a height position with a small gap between the template 10 and the wafer 20 until the imprint processing ends. Thereby, the template 10 is prevented from coming into contact with the wafer 20 and damaging the wafer 20.

When the template 10 is lowered, the droplets 110d are pressed and spread out, and the plurality of droplets 110d are all roughly integrated to form a resist layer 110s. In addition, a portion of the resist layer 110s gradually fills uneven portions of the pattern 10p on the template 10 due to capillary action.

This state is observed, for example, by the imaging element 83, and when the resist layer 110s is substantially completely filled into the unevenness of the pattern 10p, fine alignment is performed while observing the alignment marks on the template 10 and the wafer 20, for example, by the imaging element 84.

Fine alignment is processing in which the template 10 is slid along the surface of the wafer 20 while in contact with the resist layer 110s, and the template 10 and the wafer 20 are aligned more precisely so that the alignment marks on the template 10 and the wafer 20 overlap each other.

The reason why the fine alignment is performed after the resist layer 110s is filled into the unevenness of the pattern 10p is that the visibility of the alignment marks is improved when the unevenness of the pattern 10p is filled. However, the filling of the unevenness of the pattern 10p with the resist layer 110s and the fine alignment may be performed in parallel. Thereby, it is possible to improve the throughput of the imprint processing.

After the fine alignment ends, the template 10 is irradiated from above with ultraviolet light or the like from the light source 89 of the imprint device 1 to cure the resist layer 110s. Thereby, the pattern 10p of the template 10 is transferred to the resist layer 110s.

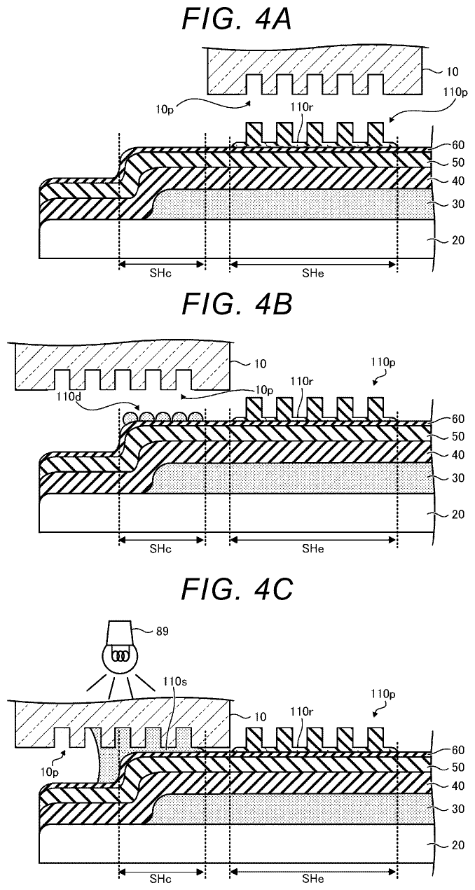

As shown in FIG. 4A, the template 10 is released from the resist pattern 110p. Thereby, the resist pattern 110p, in which the pattern 10p of the template 10 has been transferred to the resist layer 110s, is formed in the shot region SHe.

The resist pattern 110p is formed to include a resist residual film 110r at the bottom between the patterns. As described above, the resist residual film 110r is formed by maintaining the template 10 at a height position where a small gap is formed between the template 10 and the wafer 20 during the imprint processing.

Next, the imprint processing for the shot region SHc, which is disposed at the outer periphery of the wafer 20 and is partially missing, is shown below.

As shown in FIG. 4B, even in the shot region SHc having a missing portion, the droplets 110d are dropped by the droplet dropping device 87 of the imprint device 1. At this time, in the shot region SHc which is partially missing, the droplets 110d are not dropped on the missing portion.

However, in the subsequent fine alignment, in order to smoothly slide the template 10 in contact with the resist layer 110s, it is preferable that the droplets 110d be disposed close to the missing portion of the shot region SHc.

Also in the shot region SHc, rough alignment of the template 10 and the wafer 20 is performed while the template 10 and the wafer 20 are spaced apart from the droplets 110d dropped in the shot region SHc.

As shown in FIG. 4C, the pattern 10p of the template 10 is brought into contact with the plurality of droplets 110d on the shot region SHc. At this time, the droplets 110d disposed in the vicinity of the missing portion of the shot region SHc may be pressed and spread to the outer periphery of the wafer 20 outside the shot region SHc.

After performing fine alignment in the above-described state, the light source 89 of the imprint device 1 irradiates the template 10 with light such as ultraviolet light from above to cure the resist layer 110s. Thereby, the pattern 10p of the template 10 is transferred to the resist layer 110s.

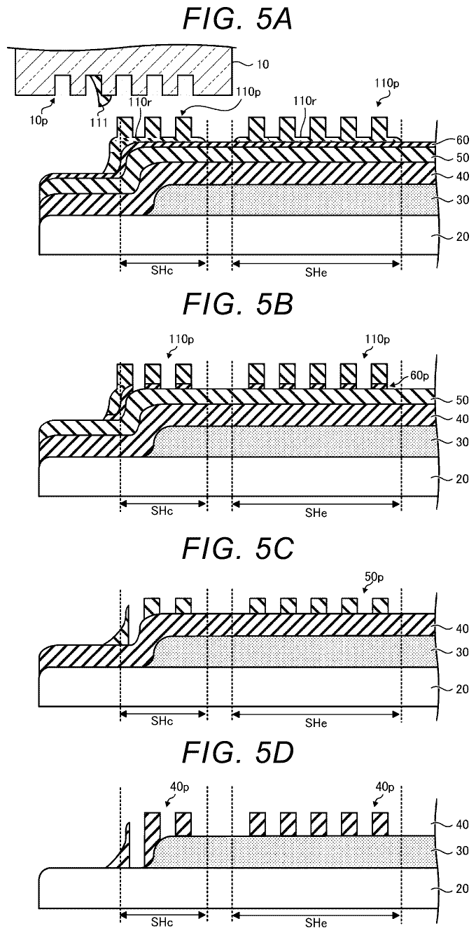

As shown in FIG. 5A, the template 10 is released from the resist pattern 110p. Thereby, the pattern 10p of the template 10 is transferred to the resist layer 110s, and the resist pattern 110p having the resist residual film 110r is formed in the shot region SHc.

When the template 10 is released from the resist pattern 110p, a portion of the resist layer 110s that has spread outside the shot region SHc may adhere to the template 10 and become a residue 111. The residue 111 is in a cured or semi-cured state due to irradiation with light from the light source 89. The semi-cured state is, for example, a state in which the viscosity is higher than that of the droplets 110d right after being dropped.

When the imprint processing for all the shot regions SH on the wafer 20 ends, the template 10, the wafer 20, and the dummy wafer 20d are removed from the imprint device 1. The wafer 20 removed from the imprint device 1 proceeds to the subsequent processing.

As shown in FIG. 5B, the resist residual film 110r of the resist pattern 110p is removed using a method such as reactive ion etching (RIE), and the exposed SOG layer 60 is etched to form an SOG pattern 60p in which the resist pattern 110p is transferred to the SOG layer 60.

As shown in FIG. 5C, the SOC layer 50 is subsequently etched using the SOG pattern 60p as a mask by a method such as RIE to form an SOC pattern 50p in which the SOG pattern 60p is transferred to the SOC layer 50. Since the resist pattern 110p and the SOC layer 50 are made of, for example, similar materials, at least the resist pattern 110p is removed due to the etching processing for the SOC layer 50.

As shown in FIG. 5D, the to-be-processed layer 40 is further etched using the SOC pattern 50p as a mask by a method such as RIE to form a pattern 40p in which the SOC pattern 50p is transferred to the to-be-processed layer 40. Thereafter, the SOC pattern 50p is removed by such as ashing processing using oxygen plasma.

Thereafter, for example, when the to-be-processed layer 40 is an insulating layer or the like, a conductive layer or the like is embedded in the pattern 40p of the to-be-processed layer 40 to form wiring lines, vias, or the like. By repeating the above-described processing a plurality of times, the semiconductor device according to the first embodiment is manufactured.

In the above-described example, the to-be-processed layer 40 is an insulating layer or the like, but the to-be-processed layer 40 may be any of other types of layers such as a conductive layer or a semiconductor layer. In addition, the SOC layer 50 and the SOG layer 60 are formed on the to-be-processed layer 40, and then the resist pattern 110p to be subjected to imprint processing is formed, but the layer configuration used when processing the to-be-processed layer 40 is not limited to the above.

### Imprint Method

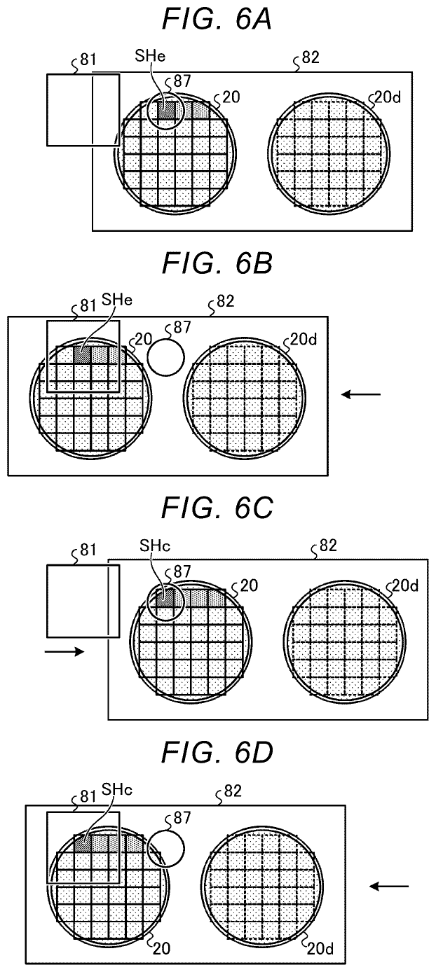

In FIGS. 3A to 5D described above, the imprint processing performed on the wafer 20 in the manufacturing method for the semiconductor device according to the first embodiment has been described. Here, details of the imprint method according to the first embodiment are described together with the operation of the imprint device 1 using FIGS. 6A to 6D, 7A to 7D, and 8A to 8B.

FIGS. 6A to 6D, 7A to 7D, and 8A to 8B are schematic top views sequentially showing a portion of a procedure of the imprint method in the imprint device 1 according to the first embodiment. The following drawings mainly show the operation of the wafer stage 82 in the imprint device 1 and the relative position of the wafer stage 82 with respect to the template stage 81 and the droplet dropping device 87.

As shown in FIG. 6A, the wafer 20 and the dummy wafer 20d are placed on the wafer stage 82 of the imprint device 1, and imprint processing is performed on the wafer 20, starting from the shot region SH on the upper right side of the page. In the drawing, two shot regions SH on the upper right side of the page, which are hatched in a slightly darker color, indicate that the imprint processing has been performed.

In FIG. 6A, the control unit 90 of the imprint device 1 controls the wafer stage 82 to move the third shot region SHe from the right on the page below the droplet dropping device 87, and then causes the droplets 110d to be dropped by the droplet dropping device 87. In the drawings, the shot region SH that is hatched in the darkest color indicates that it is currently subjected to imprint processing.

As shown in FIG. 6B, the control unit 90 controls the wafer stage 82 to move, below the template stage 81, the shot region SHe onto which the droplets 110d have been dropped, and then the template stage 81 to move up and down to execute imprint processing on that shot region SHe.

As shown in FIG. 6C, the control unit 90 controls the wafer stage 82 to move the shot region SH to be subjected to imprint processing below the droplet dropping device 87. In the example of FIG. 6C, a target to be subjected to imprint processing next is a shot region SHc that is located on the left of the shot region SH, which has been subjected to imprint processing in FIG. 6B, and has a missing portion. The control unit 90 controls the droplet dropping device 87 to drop the droplets 110d onto the shot region SHc.

As shown in FIG. 6D, the control unit 90 controls the wafer stage 82 to move, below the template stage 81, the shot region SHc onto which the droplets 110d have been dropped, and then the template stage 81 to move up and down to execute imprint processing on the shot region SHc.

Here, the shot region SHc is a missing shot that is disposed at the outer periphery of the wafer 20. For this reason, as shown in FIG. 5A described above, after the imprint processing is performed on this shot region SHc, the excess resist layer 110s that protrudes from the shot region SHc may adhere to the template 10 as the residue 111. When the next imprint processing is performed with the residue 111 adhered to the template 10, there is a concern that the residue 111 may adhere to the next shot region SH and become a particle source, and pattern formation by the imprint processing may not be performed normally.

Consequently, in the imprint device 1 according to the first embodiment, after imprint processing is performed on the shot region SHc having a missing portion, imprint processing is performed on the dummy wafer 20d. Thereby, the residue 111 adhering to the template 10 moves to the dummy wafer 20d, and the template 10 can be returned to a clean state. The operation of the imprint device 1 at that time is shown below.

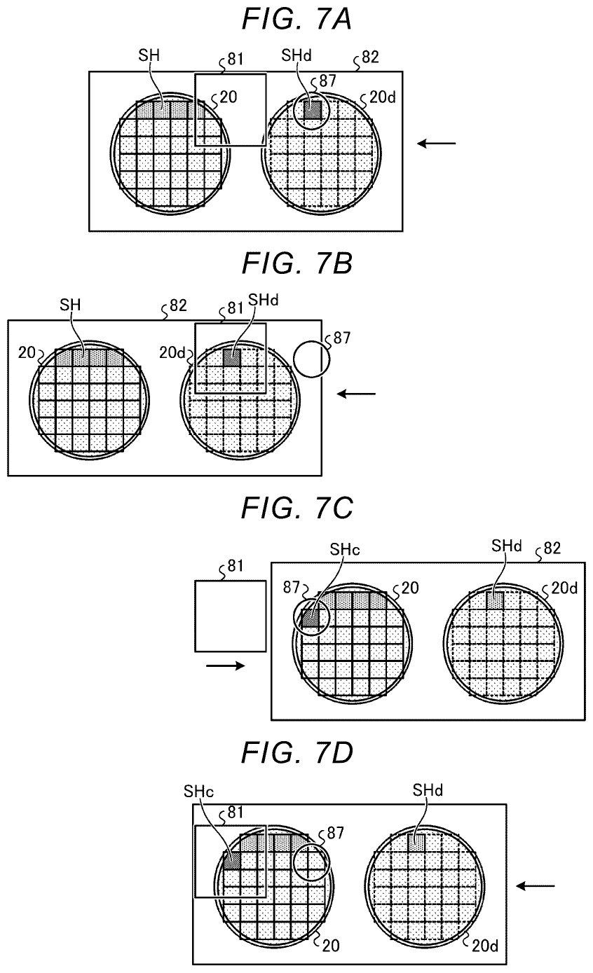

As shown in FIG. 7A, the control unit 90 controls the wafer stage 82 to move to any position other than the outer periphery of the dummy wafer 20d below the droplet dropping device 87, and then causes the droplets 110d to be dropped. The dummy wafer 20d may or may not be provided with a shot region, similar to the wafer 20. In the example of FIG. 7A, the region of the dummy wafer 20d onto which the droplets 110d are dropped is referred to as a shot region SHd for convenience.

As shown in FIG. 7B, the control unit 90 controls the wafer stage 82 to move the shot region SHd of the dummy wafer 20d below the template stage 81, and then the template stage 81 to move up and down to execute imprint processing on the shot region SHd. At this time, the resist material of the shot region SHd is also cured by emitting light from the light source 89, and the pattern 10p of the template 10 is also transferred.

Thereby, even when the residue 111 adheres to the template 10, the residue 111 can move to the shot region SHd of the dummy wafer 20d, and thus the template 10 can be cleaned.

In addition, when there is a concern that the residue 111 of the template 10 cannot be completely removed by performing imprint processing on the dummy wafer 20d once, the imprint processing may be repeatedly performed on the dummy wafer 20d a plurality of times while changing the position of imprint processing on the dummy wafer 20d.

As shown in FIG. 7C, the control unit 90 continuously performs imprint processing on the wafer 20 after the imprint processing is performed on the dummy wafer 20d. In the example of FIG. 7C, a target to be subjected to imprint processing next is a shot region SHc adjacent to the shot region SHc, which has been subjected to imprint processing in FIG. 6D described above, at the lower left of the page.

The control unit 90 controls the wafer stage 82 to move the shot region SHc below the droplet dropping device 87, and then causes the droplets 110d to be dropped by the droplet dropping device 87.

As shown in FIG. 7D, the control unit 90 controls the wafer stage 82 to move, below the template stage 81, the shot region SHc onto which the droplets 110d have been dropped, and then the template stage 81 to move up and down to execute imprint processing on the shot region SHc.

Since this shot region SHc is also a missing shot, the control unit 90 then performs imprint processing on the dummy wafer 20d as shown below.

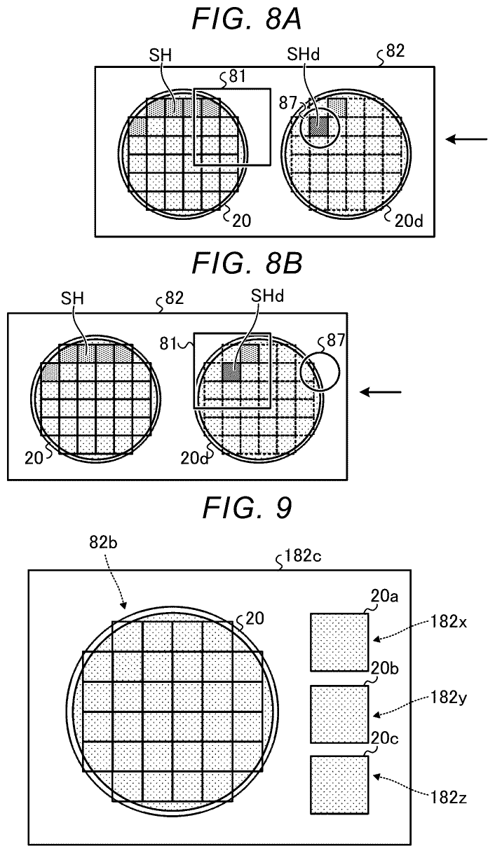

As shown in FIG. 8A, the control unit 90 controls the wafer stage 82 to move, below the droplet dropping device 87, any position other than the outer periphery of the dummy wafer 20d and an area that has been subjected to imprint processing, and then causes the droplets 110d to be dropped.

As shown in FIG. 8B, the control unit 90 controls the wafer stage 82 to move, below the template stage 81, the shot region SHd onto which the droplets 110d have been dropped, and then the template stage 81 to move up and down to execute imprint processing on the shot region SHd. Thereby, the pattern 10p of the template 10 is transferred to the shot region SHd, and the residue 111 of the template 10 moves to the dummy wafer 20d.

As described above, in the imprint device 1 according to the first embodiment, each time imprint processing is performed on a shot region SHc having a missing portion among the plurality of shot regions SH on the wafer 20, imprint processing is performed on the dummy wafer 20d once or a plurality of times.

### Summary

In a manufacturing process for a semiconductor device, imprint processing may be performed by an imprint device. Some of a plurality of shot regions provided on a wafer are missing shots disposed at the outer periphery of the wafer. After the imprint processing is performed on the missing shots, a resist residue may adhere to a template, causing defects in the next shot region.

According to the imprint device 1 of the first embodiment, after imprint processing is performed on the shot region SHc, which is disposed at the outer periphery of the wafer 20 and is partially missing, among the plurality of shot regions SH, imprint processing is performed in which the template 10 is pressed against the uncured droplets 110d disposed on the dummy wafer 20d, and the pattern 10p of the template 10 is transferred to the droplets 110d of the dummy wafer 20d. Thereby, it is possible to curb defects in the imprint processing after processing the shot region SHc having a missing portion.

### First Modification Example

Next, an imprint device according to a first modification example of the first embodiment will be described with reference to FIG. 9. The imprint device according to the first modification example differs from that in the first embodiment described above in that dummy chips 20a to 20c are accommodated instead of the dummy wafer 20d.

FIG. 9 is a top view showing an example of a wafer stage 182c of the imprint device according to the first modification example of the first embodiment. In FIG. 9, the same components as those in the first embodiment described above are denoted by the same reference numerals, and the description thereof may be omitted.

As shown in FIG. 9, the imprint device according to the first modification example includes the wafer stage 182c. The wafer stage 182c includes a wafer chuck 82b capable of chucking the wafer 20, and chip chucks 182x to 182z capable of chucking dummy chips 20a to 20c. The dummy chips 20a to 20c may be obtained by cutting the above-described dummy wafer 20d into chip shapes. Each of the dummy chips 20a to 20c may include a semiconductor substrate, an insulating substrate, a conductive substrate, or the like similar to the dummy wafer 20d.

The chip chucks 182x to 182z are provided on the wafer stage 182c so as to be adjacent to the wafer chuck 82b. Thereby, the plurality of dummy chips 20a to 20c can be disposed in proximity to the wafer 20.

The individual dummy chips 20a to 20c disposed on the chip chucks 182x to 182z have a size that is larger than a size of one shot region SH of the wafer 20. Alternatively, each of the dummy chips 20a to 20c may have a size corresponding to a plurality of shot regions SH.

In addition, the number of chip chucks 182x to 182z provided on the wafer stage 182c can be any number. However, it is preferable that the total area of the dummy chips 20a to 20c that can be placed on the chip chucks 182x to 182z be equal to or larger than an area in which imprint processing can be performed for the number of missing shot regions SHc on the wafer 20.

The number of missing shot regions SHc disposed on the wafer 20 is approximately several, and an area required for the imprint processing performed to remove template residues is smaller than the area of the dummy wafer 20d in a wafer state.

According to the imprint device of the first modification example, the dummy chips 20a to 20c are used for imprint processing for removing the residue 111 instead of the dummy wafer 20d, and thus it is possible to reduce the size of the wafer stage 182c and achieve space saving.

According to the imprint device of the first modification example, the same effects as those in the first embodiment described above are also achieved.

### Second Modification Example

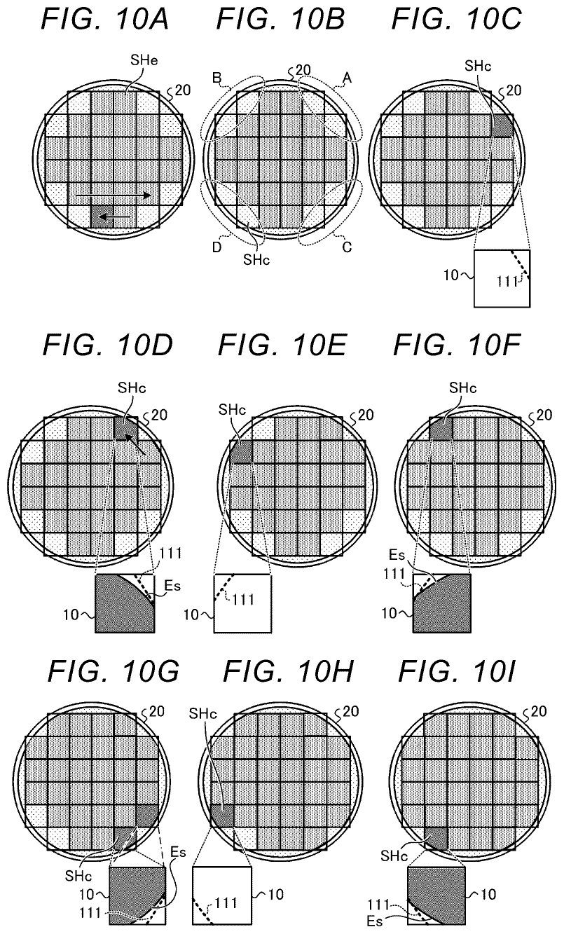

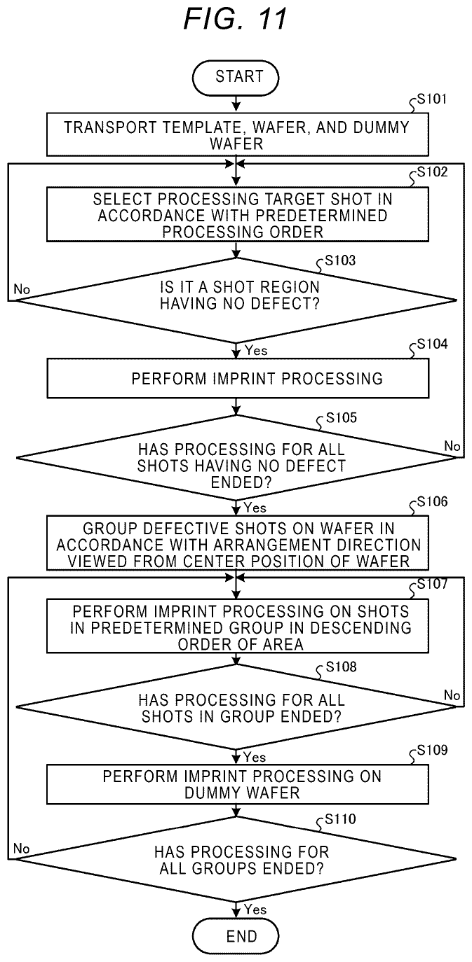

Next, an imprint device according to a second modification example of the first embodiment will be described with reference to FIGS. 10A to 10I and 11. The imprint device according to the second modification example differs from that in the first embodiment described above in that the number of times the dummy wafer 20d is used is reduced.

In the following drawings, the same components as those in the first embodiment described above are denoted by the same reference numerals, and the description thereof may be omitted.

FIGS. 10A to 10I are a top view sequentially showing a portion of a procedure of imprint processing in the imprint device according to the second modification example of the first embodiment.

As shown in FIG. 10A, in the imprint device according to the second modification example, for example, a shot region SHe on the wafer 20 which has no missing portion is processed with preference over a shot region SHc having a missing portion.

That is, the imprint device according to the second modification example performs imprint processing on a plurality of shot regions SHe in the uppermost row on the upper side of the paper on the wafer 20, from one end side to the other side in the right-left direction of the paper. Thereafter, imprint processing is performed on a plurality of shot regions SHe belonging to a row adjacent to these shot regions SHe on the lower side of the paper, from one end side to the other in the right-left direction of the paper. At this time, a method of proceeding with the processing in the opposite direction to the shot regions SHe in the first row is adopted.

In this manner, imprint processing is performed sequentially for a row of shot regions SH arranged in the horizontal direction of the paper, and each time the processing for one row ends, imprint processing is performed sequentially in the opposite direction for a row of shot regions SH adjacent in the vertical direction of the paper. This processing order is also referred to as a raster scanning method. This processing order of the imprint processing is set in advance, for example, in a control unit or the like of the imprint device.

As shown in FIG. 10B, when imprint processing for all shot regions SHe on the wafer 20, which has no missing portion, ends, the imprint device according to the second modification example groups the missing shot regions SHc on the wafer 20 in accordance with a direction as viewed from the center portion of the wafer 20.

Specifically, the shot regions SHc having a missing portion are disposed, for example, in the vicinity of the outer edge of the wafer 20 on the upper right side, upper left side, lower right side, and lower left side of the paper when viewed from the center portion of the wafer 20. Thus, for example, the shot regions SHc disposed in the vicinity of the outer edge on the upper right side of the paper are grouped as a group A, the shot regions SHc disposed in the vicinity of the outer edge on the upper left side of the paper are grouped as a group B, the shot regions SHc disposed in the vicinity of the outer edge on the lower right side of the paper are grouped as a group C, and the shot regions SHc disposed in the vicinity of the outer edge on the lower left side of the paper are grouped as a group D.

In addition, when performing imprint processing on a plurality of missing shot regions SHc, the imprint device according to the second modification example successively processes the shot regions SHc belonging to the same group in descending order of size (area).

As shown in FIG. 10C, the imprint device according to the second modification example performs imprint processing on the missing shot region SHc at the right end of the paper in the second row, the shot region SHc belonging to the group A among the plurality of groups A to D. The shot region SHc at the right end of the paper in the second row has the largest area among the missing shots belonging to the group A.

After processing the shot region SHc, there is a possibility that the residue 111 will adhere to the template 10 in the portion in contact with the missing portion of the shot region SHc, as shown by a dashed line in the drawing.

As shown in FIG. 10D, next, the imprint device according to the second modification example processes the missing shot region SHc on the upper left side in the shot region SHc, which belongs to the same group A and has an area smaller than the shot region SHc at the right end of the second row of the paper. It should be noted that the imprint processing is not performed on the dummy wafer 20d between the imprint processing for these shot regions SHc, and these shot regions SHc are processed successively.

In this manner, when a plurality of shot regions SHc belonging to the same group A are processed successively, the processing proceeds from the shot region SHc with a smaller missing portion and a larger area to the shot region SHc with a larger missing portion and a smaller area.

Thereby, as shown in FIG. 10C described above, even when the residue 111 adheres to the template 10 due to the previously processed shot region SHc, when the next shot region SHc is processed, the portion of the template 10 to which the residue 111 adheres is located outside the shot region SHc.

Thus, even when a plurality of shot regions SHc are successively processed without performing imprint processing on the dummy wafer 20d in between, the residue 111 of the template 10 is prevented from affecting the shot regions SHc to be processed later.

Furthermore, when the imprint processing for the plurality of shot regions SHc belonging to the group A is completed, the imprint device according to the second modification example executes imprint processing on the dummy wafer 20d. Thereby, the residue 111 that adheres to the template 10 due to the processing of the plurality of missing shots of the group A is removed.

As shown in FIG. 10E, the imprint device according to the second modification example performs imprint processing, for example, on the shot region SHc that has the largest area among the shot regions SHc belonging to the group B. At this time, the residue 111 may also adhere to the template 10.

As shown in FIG. 10F, the imprint device according to the second modification example performs imprint processing on the shot regions SHc belonging to the group B in descending order of area, without performing imprint processing on the dummy wafer 20d. When the processing of the plurality of shot regions SHc belonging to the group B is completed, the imprint device according to the second modification example executes imprint processing on the dummy wafer 20d.

In this manner, the imprint device according to the second modification example executes imprint processing on the plurality of missing shot regions SHc on the wafer 20 in the same manner as above while appropriately performing imprint processing on the dummy wafer 20d.

As shown in FIG. 10G, for example, the shot regions SHc belonging to the group C are processed in descending order of area. After the processing of the shot regions SHc in the group C ends, imprint processing is performed on the dummy wafer 20d.

As shown in FIG. 10H, imprint processing is then performed on the shot region SHc with the largest area which belongs to the group D.

As shown in FIG. 10I, imprint processing is performed on the shot regions SHc belonging to the group D in descending order of area, and the processing of all of the shot regions SH on the wafer 20 to be subjected to imprint processing ends.

As described above, the imprint processing in the imprint device according to the second modification example ends.

FIG. 11 is a flow diagram sequentially showing a portion of the procedure of the imprint processing in the imprint device according to the second modification example of the first embodiment.

As shown in FIG. 11, the template 10, the wafer 20, and the dummy wafer 20d are transported into the imprint device according to the second modification example (step S101). The control unit provided in the imprint device according to the second modification example selects a shot region SH to be processed from among the plurality of shot regions SH on the wafer 20 in accordance with a standard processing order that is set in advance, such as a raster scanning method (step S102).

At this time, the control unit in the second modification example determines whether a shot region SH that is to be subjected to imprint processing from now is a shot that belongs to a predetermined group and has no missing portion (step S103). When the shot region SH is a shot region SHe that has no missing portion (step S103: Yes), the control unit performs imprint processing on the shot region SHe (step S104).

When the selected shot region SH is a shot region SHc that has a missing portion (step S103: No), the control unit does not proceed to the processing of step S104, but selects a shot region SH to be subjected to imprint processing next in accordance with the processing of step S102.

After the imprint processing of step S104, the control unit in the second modification example determines whether processing for all of the shot regions SHe having no missing portion has ended (step S105). When there is any unprocessed shot region SHe having no missing portion (step S105: No), the control unit repeats the processing from step S102.

When processing for all of the shot regions SHe having no missing portion has ended (step S105: Yes), the control unit in the second modification example groups the missing shots on the wafer 20 in accordance with the arrangement direction as viewed from the center position of the wafer 20 (step S106).

In addition, the control unit in the second modification example performs imprint processing on shot regions SHc of a predetermined group in descending order of area (step S107).

Then, the control unit proceeds with the processing while determining whether the processing for all of the shot regions SHc in the group has ended at an appropriate timing (step S108). That is, when there is an unprocessed shot region SHc in the group (step S108: No), the control unit repeats the processing of step S107.

When the processing for all of the shot regions SHc in the group has ended (step S108: Yes), the control unit executes imprint processing on the dummy wafer 20d (step S109).

After the processing of step S109 has ended, the control unit determines whether the imprint processing for all of the groups has ended (step S110). When the processing for all of the groups has ended (step S110: Yes), the control unit ends the imprint processing for the wafer 20, and when there is an unprocessed shot region SHc (step S110: No), the processing from step S107 is repeated.

As described above, the imprint processing in the imprint device according to the second modification example ends.

According to the imprint method according to the second modification example, shot regions SHc, which have a missing portion among a plurality of shot regions SH and disposed at an outer edge of the wafer 20 in a predetermined direction from the center portion of the wafer 20, are classified into predetermined groups, imprint processing is performed successively on a plurality of shot regions SHc belonging to the same group in order from the shot region SHc with the smallest missing portion, and after the imprint processing for all of the shot regions SHc ends, imprint processing is performed on the dummy wafer 20d.

Thereby, it is possible to reduce the number of times imprint processing performed on the dummy wafer 20d and to improve the throughput of the imprint device. In addition, among a plurality of shot regions SHc belonging to the same group, processing is performed on the shot regions SHc in order from the shot region SHc with the smallest missing portion, and thus it is possible to curb the effect of the residue 111 of the template 10 on the shot regions SHc without performing imprint processing on the dummy wafer 20d.

According to the imprint device in the second modification example, the same effects as those in the first embodiment described above are also achieved.

### Second Embodiment

A second embodiment will be described in detail below with reference to the drawings. An imprint device according to the second embodiment differs from that in the first embodiment described above in that a wafer stage on which a wafer 20 is placed and a wafer stage on which a dummy wafer 20d is placed are provided independently.

In the following drawings, the same components as those in the first embodiment described above are denoted by the same reference numerals, and the description thereof may be omitted.

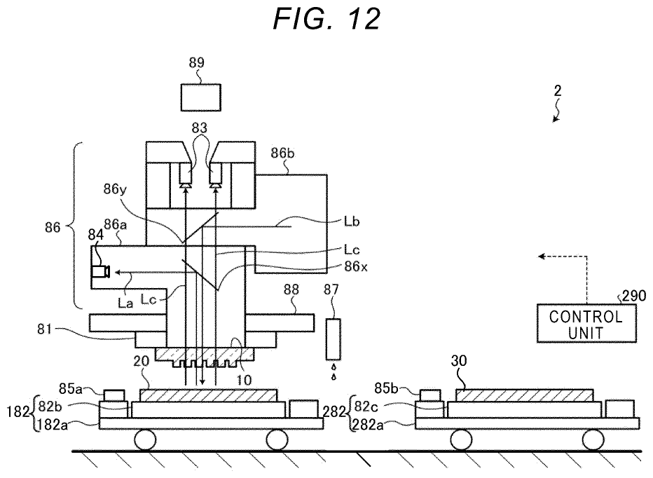

FIG. 12 is a schematic diagram showing an example of a configuration of an imprint device 2 according to the second embodiment.

As shown in FIG. 12, the imprint device 2 according to the second embodiment includes wafer stages 182 and 282 and a control unit 290 instead of the wafer stage 82 and the control unit 90 of the imprint device 1 according to the first embodiment described above.

The wafer stage 182 includes a main body 182a, a wafer chuck 82b on which a wafer 20 is placed and chucked, and a reference mark 85a used for alignment when placing the wafer 20.

The wafer stage 282 includes a main body 282a, a wafer chuck 82c on which the wafer 20 is placed and chucked, and a reference mark 85b used for alignment when placing the wafer 20.

The wafer stages 182 and 282 are provided independently of each other and are capable of moving independently within parallel planes (horizontal planes).

Similarly to the control unit 90 according to the first embodiment described above, the control unit 290 is, for example, a computer including a hardware processor, a memory, an HDD, and the like and controls each part of the imprint device 2, including the wafer stages 182 and 282.

In this manner, by including the wafer stages 182 and 282 controlled independently of each other, the imprint device 2 according to the second embodiment can proceed with a portion of imprint processing for a shot region SH on the wafer 20 and a portion of imprint processing for the dummy wafer 20d in parallel.

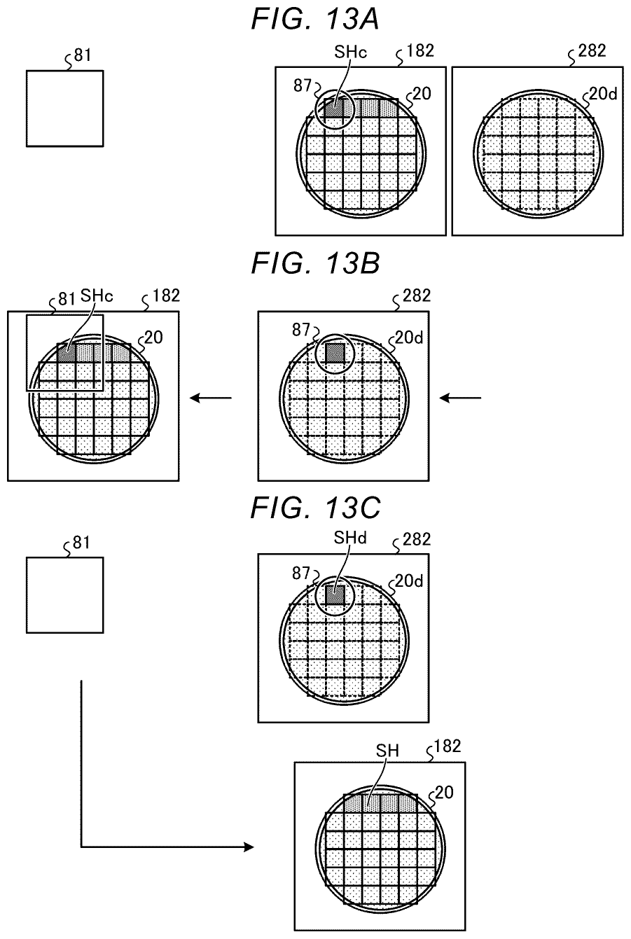

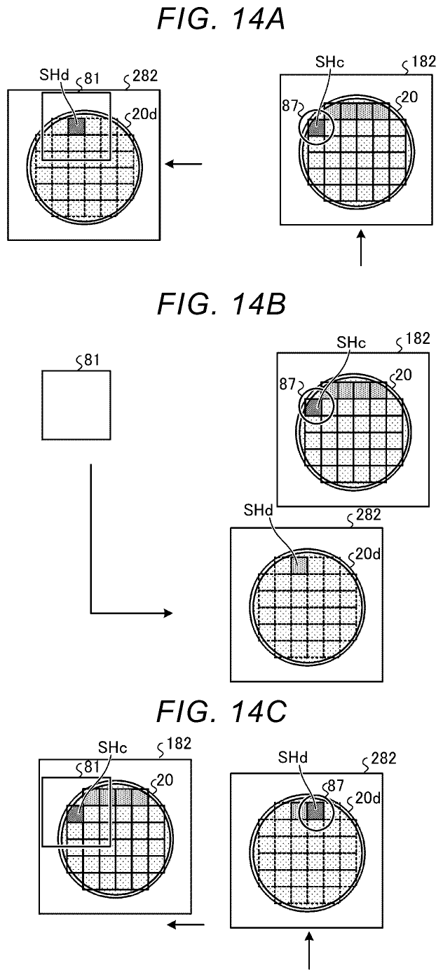

FIGS. 13A to 14C are schematic top views sequentially showing a portion of a procedure of an imprint method in the imprint device 2 according to the second embodiment. The following drawings mainly show the operations of the wafer stages 182 and 282 in the imprint device 2 and the relative positions of the wafer stages 182 and 282 with respect to a template stage 81 and a droplet dropping device 87.

As shown in FIG. 13A, the wafer 20 is placed on the wafer stage 182 of the imprint device 2, and the dummy wafer 20d is placed on the wafer stage 282. Further, in the imprint device 2 according to the second embodiment, the control unit 290 performs imprint processing on the wafer 20, for example, in order from a shot region SH on the upper right side of the page.

In FIG. 13A, the control unit 290 controls the wafer stage 182 to move a missing shot region SHc, which is the fourth shot region from the right on the paper, below the droplet dropping device 87, and then causes droplets 110d to be dropped by the droplet dropping device 87.

As shown in FIG. 13B, the control unit 290 controls the wafer stage 182 to move, below the template stage 81, the shot region SHc onto which the droplets 110d have been dropped, and then the template stage 81 to move up and down to execute imprint processing on the shot region SHe.

In parallel with this, the control unit 290 controls the wafer stage 282 to move any position other than the outer periphery of the dummy wafer 20d below the droplet dropping device 87, and then causes the droplets 110d to be dropped.

As shown in FIG. 13C, the control unit 290 controls the wafer stage 182 to move the wafer 20 in which the imprint processing for the shot region SHc on the upper left side of the page has ended, away from the position below the template stage 81.

As shown in FIG. 14A, the control unit 290 controls the wafer stage 282 to move, below the template stage 81, the shot region SHd of the dummy wafer 20d on which the droplets 110d have been dropped, and then the template stage 81 to move up and down to execute imprint processing on the shot region SHd.

In parallel with this, the control unit 290 sets, as a target to be subjected to imprint processing next, a shot region SHc adjacent to the shot region SHc, which has been subjected to the imprint processing in FIG. 13B described above, on the lower left side of the page, controls the wafer stage 182 to move the shot region SHc below the droplet dropping device 87, and then causes the droplets 110d to be dropped by the droplet dropping device 87.

As shown in FIG. 14B, the control unit 290 controls the wafer stage 282 to move the dummy wafer 20d in which the imprint processing for the shot region SHd has ended, away from the position below the template stage 81.

As shown in FIG. 14C, the control unit 290 controls the wafer stage 182 to move, below the template stage 81, the shot region SHc onto which the droplets 110d have been dropped, and then the template stage 81 to move up and down to execute imprint processing on the shot region SHe.

In parallel with this, the control unit 290 controls the wafer stage 282 to move, below the droplet dropping device 87, a position other than the outer periphery of the dummy wafer 20d and excluding the above-described shot region SHd that has been subjected to imprint processing, and then causes the droplets 110d to be dropped.

As described above, in the imprint device 2 according to the second embodiment, for example, while imprint processing is being performed on a missing shot region SHc of the wafer 20, droplets are dropped onto the dummy wafer 20d to prepare for imprint processing for the dummy wafer 20d which will be performed after the processing of the above-described shot region SHc. In addition, while imprint processing is being performed on the dummy wafer 20d, droplets are dropped onto the wafer 20 to prepare for imprint processing for the next shot region SH.

While shot regions SHe having no missing portion on the wafer 20 are being processed successively, the position of the wafer stage 182 on which the wafer 20 is placed and the position of the wafer stage 282 on which the dummy wafer 20d is placed are not interchanged.

According to the imprint device 2 in the second embodiment, the wafer stage 182 on which the wafer 20 can be placed and the wafer stage 282 which is provided independently of the wafer stage 182 and on which the dummy wafer 20d can be placed are provided. Thereby, a portion of the imprint processing for the wafer 20 and a portion of the imprint processing for the dummy wafer 20d can be performed in parallel, improving the throughput of the imprint device 2.

According to the imprint device 2 in the second embodiment, the same effects as those in the first embodiment described above are also achieved.

### Third Embodiment

A third embodiment will be described in detail below with reference to the drawings. An imprint device according to the third embodiment differs from that in the first embodiment described above in that imprint processes can be performed in parallel by a plurality of templates.

In the following drawings, the same components as those in the first embodiment described above are denoted by the same reference numerals, and the description thereof may be omitted.

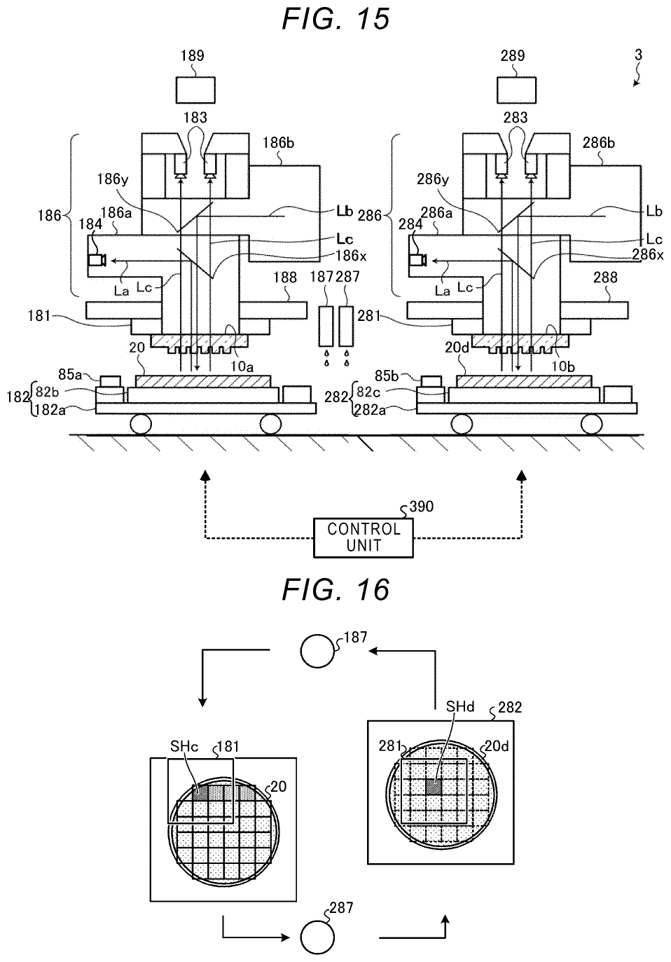

FIG. 15 is a schematic diagram showing an example of a configuration of an imprint device 3 according to the third embodiment.

As shown in FIG. 15, in the imprint device 3 according to the third embodiment, substantially all of the main components of the imprint device 3 are duplicated in addition to the wafer stages 182 and 282 of the imprint device 2 according to the second embodiment described above.

That is, the imprint device 3 according to the third embodiment includes a template stage 181, a wafer stage 182, imaging elements 183 and 184, a reference mark 85a, an alignment unit 186, a droplet dropping device 187, a stage base 188, and a light source 189. The imprint device 3 also includes a template stage 281, a wafer stage 282, imaging elements 283 and 284, a reference mark 85b, an alignment unit 286, a droplet dropping device 287, a stage base 288, and a light source 289. The imprint device 3 also includes a control unit 390.

The template stages 181 and 281, the wafer stages 182 and 282, the imaging elements 183, 184, 283, and 284, the reference marks 85a and 85b, the alignment units 186 and 286, the droplet dropping devices 187 and 287, the stage bases 188 and 288, the light sources 189 and 289, and the control unit 390 have the same functions as the template stage 81, the wafer stage 82, the imaging elements 83 and 84, the reference mark 85, the alignment unit 86, the droplet dropping device 87, the stage base 88, the light source 89, and the control unit 90 in the first embodiment described above.

More specifically, the wafer stages 182 and 282 of the imprint device 3 according to the third embodiment are configured in the same manner as the wafer stages 182 and 282 according to the second embodiment described above.

The template stages 181 and 281 are capable of holding templates 10a and 10b, respectively. The templates 10a and 10b are designed according to the same specification in imprint processing for a single wafer 20.

The alignment unit 186 includes a detection system 186a and an illumination system 186b. The alignment unit 286 includes a detection system 286a and an illumination system 286b. The detection systems 186a and 286a and the illumination systems 186b and 286b are configured in the same manner as the detection system 86a and the illumination system 86b in the first embodiment described above.

The detection system 186a and the illumination system 186b include mirrors 186x and 186y, respectively. The detection system 286a and the illumination system 286b include mirrors 286x and 286y, respectively. The mirrors 186x, 286x, 186y, and 286y are configured in the same manner as the mirrors 86x and 86y in the first embodiment described above, respectively.

The droplet dropping device 187 drops a resist onto the wafer 20 before imprint processing using the template 10a or onto a dummy wafer 20d. The droplet dropping device 287 drops a resist onto the wafer 20 before imprint processing using the template 10b or onto the dummy wafer 20d.

The light source 189 emits light such as ultraviolet light onto the wafer 20 during the imprint processing using the template 10a or onto the dummy wafer 20d. The light source 289 emits light such as ultraviolet light onto the wafer 20 during the imprint processing using the template 10b or onto the dummy wafer 20d.

The control unit 390 controls the template stage 181, the wafer stage 182, the reference mark 85a, the alignment unit 186 including the imaging elements 183 and 184, the droplet dropping device 187, the stage base 188, and the light source 189. The control unit 390 also controls the template stage 281, the wafer stage 282, the reference mark 85b, the alignment unit 286 including the imaging elements 283 and 284, the droplet dropping device 287, the stage base 288, and the light source 289.

As described above, the imprint device 3 according to the third embodiment has substantially all of a plurality of main components, and thus imprint processes for the wafer 20 and the dummy wafer 20d can be executed in parallel.

FIG. 16 is a schematic top view sequentially showing a portion of a procedure of an imprint method in the imprint device 3 according to the third embodiment.

FIG. 16 shows a state where the wafer stage 182 having the wafer 20 placed thereon is located below the template stage 181, and the wafer stage 282 having the dummy wafer 20d placed thereon is located below the template stage 281.

In the example of FIG. 16, droplets 110d have been dropped onto a predetermined shot region SHc of the wafer 20 by the droplet dropping device 187. Thus, imprint processing is executed on the shot region SHc of the wafer 20 by the template 10a mounted on the template stage 181. Since the shot region SHc is a missing shot, residues 111 may adhere to the template 10a at this time.

In addition, droplets 110d have been dropped onto a predetermined shot region SHd of the dummy wafer 20d by the droplet dropping device 287. Thus, imprint processing is executed on the shot region SHd of the dummy wafer 20d by the template 10b mounted on the template stage 281.

Thereafter, the wafer stage 182 having the wafer 20 placed thereon is moved to a position below the droplet dropping device 287, and droplets 110d are dropped onto the shot region SH to be subjected to imprint processing next. In addition, the wafer stage 182 is moved further below the template stage 281, and imprint processing is performed by the template 10b, which has been cleaned by the imprint processing performed on the dummy wafer 20d. For this reason, the effect of the residues 111 and the like on the wafer 20 is curbed.

On the other hand, the wafer stage 282 having the dummy wafer 20d placed thereon is moved to a position below the droplet dropping device 187 while the droplet dropping device 287 is dropping droplets 110d onto the wafer 20, and the droplets 110d are dropped at predetermined positions. In addition, while imprint processing is being executed on the wafer 20 using the template 10b, the wafer stage 282 is moved below the template stage 181, and imprint processing is performed using the template 10a. Thereby, if the residues 111 have adhered to the template 10a due to the imprint processing performed on the shot region SHc described above, the template 10a can be cleaned.

In this manner, for example, each time a shot region SHc having a missing portion on the wafer 20 is processed, the positions of the wafer stages 182 and 282 are interchanged, and one of the templates 10a and 10b is cleaned by the dummy wafer 20d.

While a shot region SHe having no missing portion on the wafer 20 is processed, the positions of the wafer stages 182 and 282 are not interchanged as described above, and imprint processing is performed successively on a plurality of shot regions SHe on the wafer 20 by any one of the templates 10a and 10b.

According to the imprint device 3 in the third embodiment, the imprint device 3 includes the template 10a having a pattern to be transferred to a resist layer on the wafer 20 or the dummy wafer 20d, and the template 10b having a pattern to be transferred to a resist layer on the wafer 20 or the dummy wafer 20d.

Thereby, the imprint processing for the wafer 20 and the imprint processing for the dummy wafer 20d can be performed in parallel, and the templates 10a and 10b to which the residues 111 may adhere can be cleaned before the next imprint processing for the wafer 20. Thus, it is possible to further improve the throughput of the imprint device 3.

According to the imprint device 3 of the third embodiment, the same effects as those in the first embodiment described above are also achieved.

The imprint device 3 according to the third embodiment described above includes one wafer stage 182 on which the wafer 20 is placed, and one wafer stage 282 on which the dummy wafer 20d is placed. However, the imprint device 3 may include a plurality of wafer stages on which the wafer 20 is placed.

The number of shot regions SHc having a missing portion on the wafer 20 is smaller than the number of shot regions SHe having no missing portion, and the number of times imprint processing is performed on the wafer 20 is greater than the number of times imprint processing is performed on the dummy wafer 20d. Thus, the number of wafers 20 that can be transported into the imprint device 3 is increased as compared to the number of dummy wafers 20d, and thus when imprint processing is not performed on the dummy wafer 20d, it is possible to perform imprint processes on a plurality of wafers 20 in parallel using the two templates 10a and 10b. Thereby, it is possible to increase an operation rate of the two templates 10a and 10b and further improve a throughput.

### Fourth Embodiment

A fourth embodiment will be described in detail below with reference to the drawings. An imprint device according to the fourth embodiment differs from that in the first embodiment described above in that a light shielding plate that shields light from a light source is provided. The imprint device according to the fourth embodiment does not include a wafer chuck 82c, as compared to the first embodiment.

In the following drawings, the same components as those in the first embodiment described above are denoted by the same reference numerals, and the description thereof may be omitted.

### Example of Configuration of Imprint Device

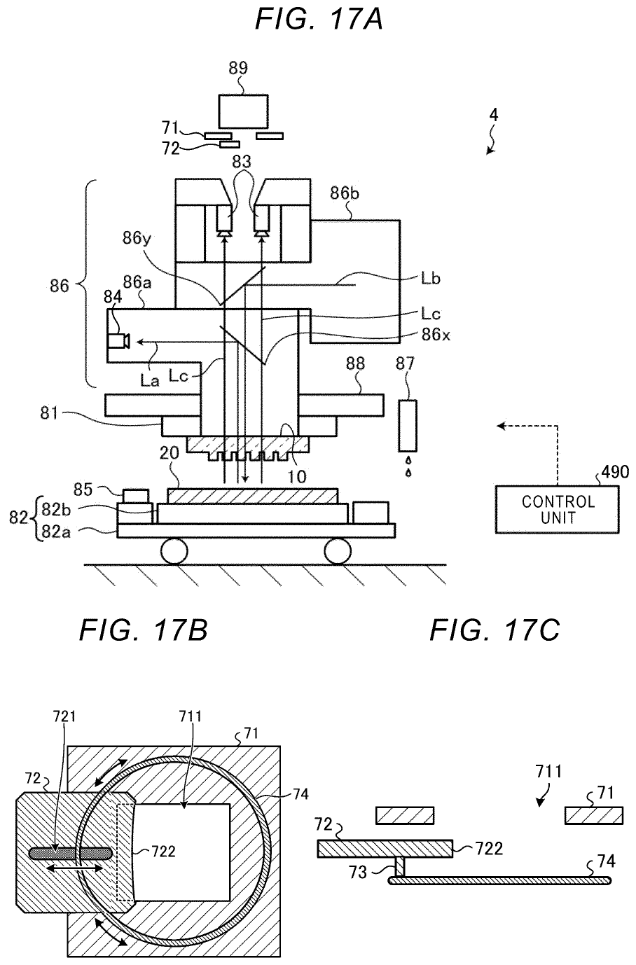

FIGS. 17A to 17C are a schematic diagram showing an example of a configuration of an imprint device 4 according to the fourth embodiment. More specifically, FIG. 17A is a schematic diagram showing the overall configuration of the imprint device 4 according to the fourth embodiment, FIG. 17B is a schematic diagram showing light shielding plates 71 and 72 of the imprint device 4 viewed from below, and FIG. 17C is a cross-sectional view of the light shielding plates 71 and 72.

As shown in FIG. 17A, the imprint device 4 according to the fourth embodiment includes the light shielding plates 71 and 72 in addition to the components in the first embodiment described above. In addition, instead of the control unit 90 according to the first embodiment described above, the imprint device 4 includes a control unit 490 that has a function of controlling each part of the imprint device 4, including the light shielding plates 71 and 72.

The light shielding plates 71 and 72 are located in the vicinity of a light source 89 and on the optical path of light emitted from the light source 89. In addition, the light shielding plates 71 and 72 overlap each other in the up-down direction with respect to the optical path of the light emitted from the light source 89, for example. The light shielding plates 71 and 72 are made of a material that shields light emitted from the light source 89, such as a metal.

However, either of the light shielding plates 71 and 72 may be disposed closer to the light source 89. That is, as in the example of FIGS. 17A to 17C, the light shielding plate 71 may be disposed on a side closer to the light source 89, and the light shielding plate 72 may be disposed on a side farther from the light source 89. Alternatively, the light shielding plate 72 may be disposed on a side closer to the light source 89, and the light shielding plate 71 may be disposed on a side farther from the light source 89.

As shown in FIGS. 17B and 17C, the light shielding plate 71 is configured in a frame shape having, for example, a rectangular opening 711. More specifically, the opening 711 is configured to have a shape similar to the above-described shot region SHe having no missing portion. Thereby, light emitted from the light source 89, partially shielded by the light shielding plate 71, and passing through the opening 711 has approximately the same shape and size as the shot region SHe on a wafer 20 when the light reaches the wafer 20.

The position of the light shielding plate 71 in the horizontal direction is fixed to the template 10. More specifically, in the imprint device 4 according to the fourth embodiment, the alignment of the template 10 and the wafer 20 in the horizontal direction is performed simply by moving a wafer stage 82 in the horizontal direction. Thus, the position of the template 10 in the horizontal direction with a predetermined position of the imprint device 4 as a reference is fixed, and the position of the light shielding plate 71 in the horizontal direction with a predetermined position of the imprint device 4 as a reference is also fixed.

However, the alignment of the template 10 and the wafer 20 in the horizontal direction may be performed by moving a template stage 81 or both the wafer stage 82 and the template stage 81 in the horizontal direction, and in this case, the light shielding plate 71 may be configured to be movable in the horizontal direction in association with the operation of the template stage 81 in the horizontal direction. Even in such a configuration, the relative position of the light shielding plate 71 with respect to the template 10 is fixed.

In addition, when viewed from the shot region SHe having no missing portion, the wafer 20 to be subjected to imprint processing may have configurations such as the area and shape of the shot region SHe which may vary occasionally. Consequently, the light shielding plate 71 may be formed by combining a plurality of metal plates and the like. Thereby, by adjusting the relative positions of the plurality of metal plates, the area and shape of the opening 711 of the light shielding plate 71 can be adjusted in accordance with various shot regions SHe.

The light shielding plate 72 is configured in, for example, a substantially rectangular flat plate shape, and is connected to a ring member 74 disposed in the vicinity of the light shielding plate 71 at a predetermined distance from the light shielding plate 71 in a direction along the optical path via an actuator 73. The actuator 73 is inserted into a groove 721 formed in the surface of the light shielding plate 72 facing the ring member 74. With such a configuration, the actuator 73 rotates and moves the light shielding plate 72 along the ring member 74, and also moves the light shielding plate 72 along the groove 721 in the horizontal direction.

The light shielding plate 72 is configured such that one side of the rectangular outer edge can protrude into the opening 711 of the light shielding plate 71 or retract from the opening 711 by the horizontal movement described above. That is, the actuator 73 is configured such that the amount of protrusion of one side of the light shielding plate 72 relative to the opening 711 can be adjusted. The light shielding plate 72 includes an arc portion 722 of which one side can protrude into the opening 711 is configured in an arc shape. The arc portion 722 of the light shielding plate 72 is configured to have a shape similar to the arc shape of the outer edge of the wafer 20 described above.

Thus, a portion of light emitted from the light source 89 that passes through the opening 711 of the light shielding plate 71 is further shielded by the light shielding plate 72 of which the amount of protrusion has been adjusted, and thus the light that reaches the wafer 20 can be adjusted to have the same shape and size as the shot region SHc having a missing portion on the wafer 20. That is, when light is matched to a shot region SHc having a large missing portion, the amount of protrusion of the light shielding plate 72 relative to the opening 711 can be increased, and when light is matched to a shot region SHc having a small missing portion, the amount of protrusion of the light shielding plate 72 relative to the opening 711 can be decreased.

In addition, owing the rotational movement described above, it is possible to change the orientation of the light shielding plate 72 that protrudes into the opening 711 of the light shielding plate 71, that is, the position of protrusion into the opening 711 of the light shielding plate 71. Thereby, the shape of light from the light source 89 can match the shot region SHc in which the position of a missing portion varies depending on the position of the arc-shaped outer periphery of the wafer 20.

### Example of Operation of Light Shielding Plate

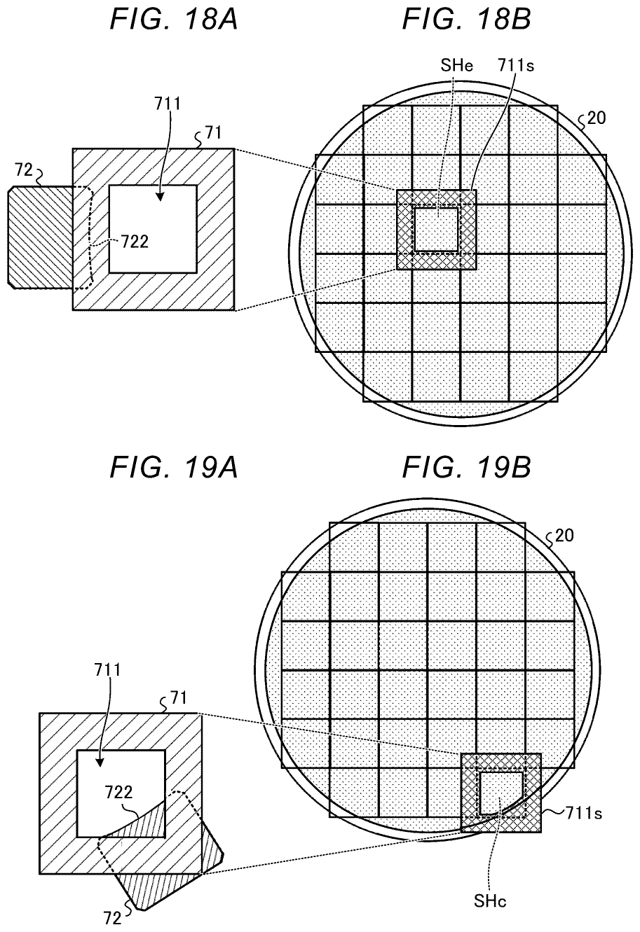

Next, an example of the operation of the light shielding plates 71 and 72 provided in the imprint device 4 according to the fourth embodiment will be described using FIGS. 18A to 21B.

FIGS. 18A to 18B, 19A to 19B, 20A to 20B, and 21A to 21B are schematic top views showing an example of the operation of the light shielding plates 71 and 72 provided in the imprint device 4 according to the fourth embodiment. More specifically, the drawings marked with A in FIGS. 18A to 21B are top views showing the positions of the light shielding plates 71 and 72, and the drawings marked with B in FIGS. 18A to 21B are top views showing the shape of light emitted from the light source 89 projected onto the wafer 20 at that time.

FIGS. 18A and 18B show an example of a case where light emitted from the light source 89 is emitted onto any shot region SHe that is located near the center of the wafer 20 and has no missing portion.

As shown in FIG. 18A, in this case, the control unit 490 of the imprint device 4 drives the actuator 73 of the light shielding plate 72 to move the entire light shielding plate 72 way from the opening 711 of the light shielding plate 71.

As shown in FIG. 18B, light emitted from the light source 89 passes through the opening 711 of the light shielding plate 71 in which the position of the light shielding plate 72 has been adjusted as described above, and reaches the shot region SHe on the wafer 20. At this time, a projection image 711s from the opening 711 of the light shielding plate 71 is shown on the wafer 20. Since the entire light shielding plate 72 has been retracted from the opening 711 of the light shielding plate 71 as described above, the projection image 711s of the opening 711 on the wafer 20 is rectangular, like the original shape of the opening 711, and substantially matches the shape of the shot region SHe.

FIGS. 19A and 19B show an example of a case where the light source 89 emits light onto a shot region SHc that is disposed on the lower right side of the paper on the wafer 20 and has a missing portion.

As shown in FIG. 19A, in this case, the control unit 490 drives the actuator 73 to adjust the position and amount of protrusion of the light shielding plate 72 from the opening 711 of the light shielding plate 71 in accordance with the missing portion of the shot region SHc.

That is, the control unit 490 drives the actuator 73 of the light shielding plate 72 to adjust the position of protrusion of the light shielding plate 72 so that the arc portion 722 of the light shielding plate 72 protrudes from the lower right side of the opening 711 of the light shielding plate 71, and to adjust the amount of protrusion of the light shielding plate 72 in the opening 711 of the light shielding plate 71 in accordance with the size of the missing portion in the shot region SHc to be irradiated with light.

As shown in FIG. 19B, light emitted from the light source 89 passes through the opening 711 of the light shielding plate 71 in which the position of the light shielding plate 72 has been adjusted as described above, and reaches the shot region SHc on the wafer 20. As described above, the lower right portion of the opening 711 is partially shielded by the light shielding plate 72, and the arc portion 722 of the light shielding plate 72 has a shape similar to the arc shape of the outer edge of the wafer 20.

Thus, the projection image 711s of the opening 711, which is partially shielded by the light shielding plate 72, on the wafer 20 has a shape that substantially matches the shape of the shot region SHc disposed on the lower right side of the wafer 20.

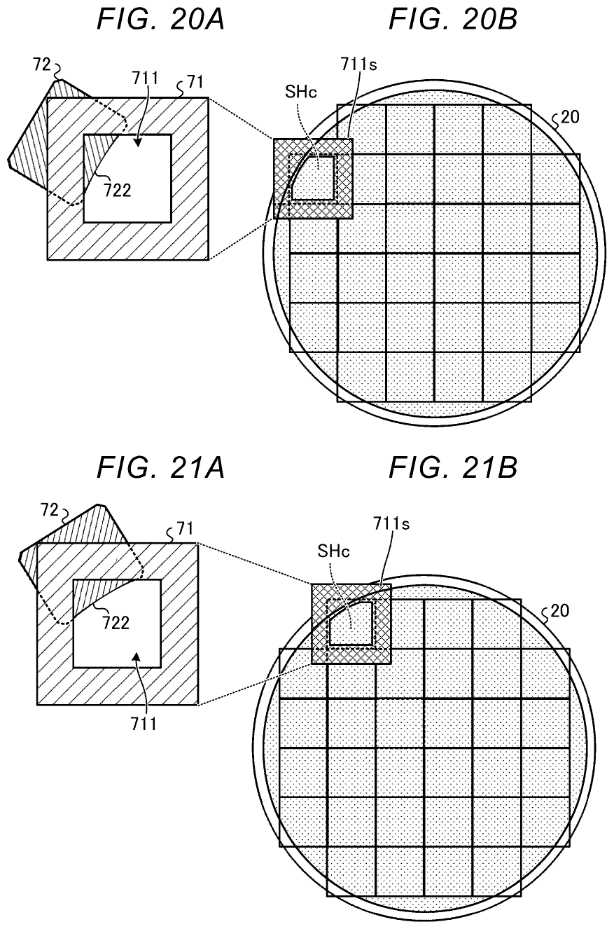

FIGS. 20A and 20B show an example of a case where the light source 89 emits light onto a shot region SHc which is disposed on the upper left side of the paper on the wafer 20 and has a missing portion.

As shown in FIG. 20A, even in this case, the control unit 490 drives the actuator 73 to adjust the position and amount of protrusion of the light shielding plate 72 from the opening 711 of the light shielding plate 71 in accordance with the missing portion of the shot region SHc.

That is, the control unit 490 drives the actuator 73 of the light shielding plate 72 to adjust the position of protrusion of the light shielding plate 72 so that the arc portion 722 of the light shielding plate 72 protrudes from the upper left side of the opening 711 of the light shielding plate 71, and to adjust the amount of protrusion of the light shielding plate 72 in the opening 711 of the light shielding plate 71 in accordance with the size of the missing portion in the shot region SHc to be irradiated with light.

As shown in FIG. 20B, light emitted from the light source 89 passes through the opening 711 of the light shielding plate 71 in which the position of the light shielding plate 72 has been adjusted as described above, and reaches the shot region SHc on the wafer 20. As described above, the upper left portion of the opening 711 is partially shielded by the light shielding plate 72, and the arc portion 722 of the light shielding plate 72 has a shape similar to the arc shape of the outer edge of the wafer 20.

Thus, the projection image 711s of the opening 711, which is partially shielded by the light shielding plate 72, on the wafer 20 has a shape that substantially matches the shape of the shot region SHc disposed on the upper left side of the wafer 20.

FIGS. 21A and 21B show an example of a case where the light source 89 emits light onto a shot region SHc that is disposed on the upper left side of the paper on the wafer 20 and has a missing portion, similar to the example of FIGS. 20A and 20B. However, the shot region SHc shown in FIGS. 21A and 21B are adjacent to the upper right side of the shot region SHc shown in FIGS. 20A and 20B, and the missing portion is located further inside than the shot region SHc shown in FIGS. 20A and 20B.

As shown in FIG. 21A, the control unit 490 drives the actuator 73 of the light shielding plate 72 to adjust the position of protrusion of the light shielding plate 72 so that the arc portion 722 of the light shielding plate 72 protrudes from the upper left side of the opening 711 of the light shielding plate 71. At this time, the position of protrusion of the light shielding plate 72 is adjusted closer to the right than in the case of FIG. 20A.

In addition, the control unit 490 controls the actuator 73 to adjust the amount of protrusion of the light shielding plate 72 in the opening 711 of the light shielding plate 71 in accordance with the size of the missing portion in the shot region SHc to be irradiated with light. At this time, the amount of protrusion of the light shielding plate 72 is adjusted to be slightly larger than in the case of FIG. 20A.

As shown in FIG. 21B, light emitted from the light source 89 passes through the opening 711 of the light shielding plate 71 in which the position of the light shielding plate 72 has been adjusted as described above, and reaches the shot region SHc on the wafer 20. Thereby, the projection image 711s of the opening 711, which is partially shielded by the light shielding plate 72, on the wafer 20 has a shape that substantially matches the shape of the shot region SHc shown in FIG. 21B.

As described above, when light is emitted onto a shot region SH (SHe, SHc) to be subjected to imprint processing, the control unit 490 of the imprint device 4 according to the fourth embodiment adjusts the position of the light shielding plate 72 in accordance with the shape of the shot region SH to be processed.

### Manufacturing Method for Semiconductor Device

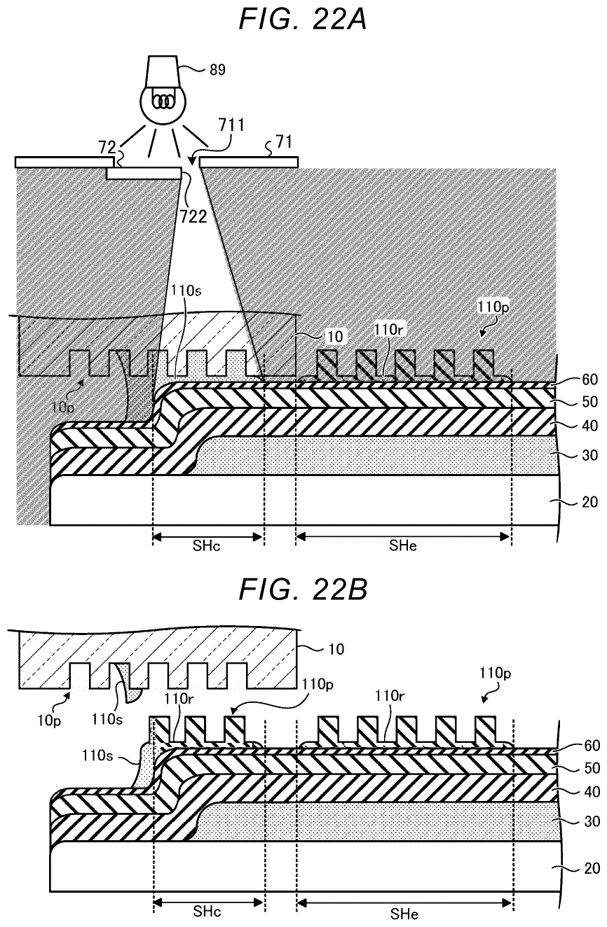

Next, a manufacturing method for a semiconductor device according to the fourth embodiment will be described with reference to FIGS. 22A to 24.

FIGS. 22A to 24 are cross-sectional views sequentially showing a portion of a procedure of the manufacturing method for the semiconductor device according to the fourth embodiment. In FIGS. 22A to 24, among manufacturing steps for the semiconductor device according to the fourth embodiment, imprint processing performed by the imprint device 4 described above will be described.

As shown in FIG. 22A, the template 10 is pressed against a shot region SHc having a missing portion, and light is emitted from the light source 89.

At this time, when the shot region SHc having a missing portion is a target to be subjected to imprint processing, the control unit 490 controls the actuator 73 to adjust the position and amount of protrusion of the light shielding plate 72 relative to the opening 711 of the light shielding plate 71, and projects light, which has a shape substantially matching the shape of the shot region SHc, onto the wafer 20. Thereby, a resist layer 110s disposed on the shot region SHc is mainly cured, and the resist layer 110s that protrudes outside the shot region SHc remains uncured.

As shown in FIG. 22B, when the template 10 is released from the cured resist layer 110s, a resist pattern 110p is formed on the shot region SHc. Furthermore, at least a portion of the uncured resist layer 110s outside the shot region SHc remains as it is outside the shot region SHc. Another portion of the uncured resist layer 110s may adhere to the template 10.

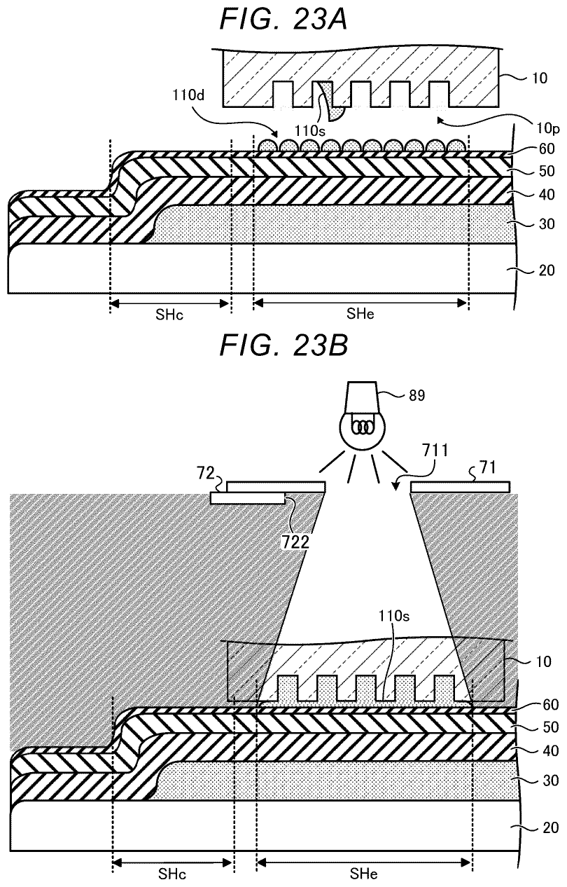

As shown in FIG. 23A, in order to start imprint processing on a shot region SHe having not missing portion subsequently to the above-described imprint processing performed on the shot region SHc, a shot region SHe on which the droplets 110d have been dropped is moved below the template 10. The uncured resist layer 110s remains adhering to the template 10.

As shown in FIG. 23B, the template 10 is pressed against the shot region SHc. Thus, the droplets 110d on the shot region SHe are pressed and layered, forming the resist layer 110s. At this time, the resist layer 110s adhering to the template 10 is uncured, and thus it mixes with the resist layer 110s on the shot region SHe, and in this state, light is emitted from the light source 89.

At this time, when the shot region SHe having no missing portion is a target to be subjected to imprint processing, the control unit 490 controls the actuator 73 to move the light shielding plate 72 way from the opening 711 of the light shielding plate 71 and projects light, which has a shape that substantially matches the shape of the shot region SHe, onto the wafer 20. Thereby, substantially the entirety of the resist layer 110s formed on the shot region SHe is cured.

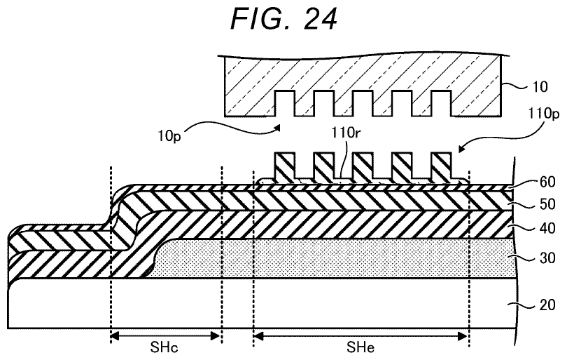

As shown in FIG. 24, when the template 10 is released from the cured resist layer 110s, the resist pattern 110p is formed on the shot region SHe.

The resist layer 110s adhering to the template 10 is mixed with the resist layer 110s before curing on the shot region SHe, and both are cured in the shape of the pattern 10p of the template 10, curbing the occurrence of defects in the resist pattern 110p on the shot region SHe. In addition, the template 10 is returned to a clean state with no resist layer 110s or the like adhering thereto.

### Summary

As described above, during imprint processing for a shot region having a missing portion, a resist layer is cured or semi-cured in a state where it protrudes outside the shot region, and thus a resist residue adheres to a template, which may cause defects during the next imprint processing.

The imprint device 4 according to the fourth embodiment includes the frame-shaped light shielding plate 71 including the opening 711 having a shape similar to the shape of the shot region SHe disposed at a position excluding the outer periphery of the wafer 20 among the plurality of shot regions SH, and the light shielding plate 72 including the arc portion 722 having a shape similar to the shape of an arc portion in a predetermined range of the outer edge of the wafer 20.

By combining such light shielding plates 71 and 72 and projecting light from the light source 89 onto the wafer 20, the shape of the shot region SHc having a missing portion can be made to substantially match the shape of the projected light. Thus, the resist layer 110s that protrudes outside the shot region SHc remains uncured, and thus even when it adheres to the template 10, the occurrence of defects in the next imprint processing can be curbed.

According to the imprint device 4 of the fourth embodiment, the relative positions of the template 10 and the light shielding plate 71 in the horizontal direction are fixed. Thereby, regardless of the presence or absence of a missing portion, the shot region SH to be processed and light projected from the opening 711 of the light shielding plate 71 can be precisely superimposed on each other.

According to the imprint device 4 of the fourth embodiment, the light shielding plate 72 is configured so that the position and distance of protrusion of the arc portion 722 in the opening 711 can be adjusted by rotating and horizontally driving the light shielding plate 72 relative to the opening 711 of the light shielding plate 71. Thereby, it is possible to adjust the shape of light projected from the opening 711 of the light shielding plate 71 so that the shape substantially matches the shot region SHc having various shapes.

According to the imprint device 4 of the fourth embodiment, when imprint processing is performed on a shot region SHc having a missing portion, the control unit 490 controls the actuator 73 to adjust the position and distance of protrusion of the arc portion 722 of the light shielding plate 72 relative to the opening 711 of the light shielding plate 71 to shield light emitted from the light source 89 so that the light has a shape similar to that of the shot region SHc. Thereby, it is possible to prevent the resist layer 110s that protrudes outside the shot region SHc from being cured.

According to the imprint device 4 of the fourth embodiment, when imprint processing is performed on a shot region SHe disposed at a position other than the outer periphery of the wafer 20, the control unit 490 controls the actuator 73 to move the light shielding plate 72 from the opening 711 of the light shielding plate 71. Thereby, it is possible to project light having a shape that substantially matches the shape of a shot region SHe having no missing portion and to curb substantially the entire resist layer 110s on the shot region SHe.

The imprint device 4 of the fourth embodiment may be provided with a light shielding layer such as a Cr layer surrounding the pattern 10p of the template 10 used in imprinting processing. In addition to the light shielding plate 71 configured in a frame shape having the opening 711, a light shielding layer is provided in the template 10 itself, and thus it is possible to further improve the accuracy of superposition of a projection image on the shot region SHe having no missing portion.

In addition, the light shielding plates 71 and 72 provided in the imprint device 4 according to the fourth embodiment can also be incorporated into the imprint device 1 and the like according to the first embodiment and the first and second modification examples described above. Thereby, in the methods according to the first embodiment and the first and second modification examples described above, the frequency with which the residue 111 adheres to the template 10 and the like, the amount of adhesion of the residue 111, and the like are reduced, and thus it is possible to more reliably curb the effect of the residue 111 on the next imprinting processing. In addition, it is possible to further reduce the frequency of cleaning the template 10 and the like using the dummy wafer 20d.

In the first to fourth embodiments and first and second modification examples described above, droplets 110d of a resist material are dropped onto a shot region SH by the droplet dropping device 87, and imprint processing is performed. However, the resist material may be applied to the entire surface of the wafer 20 in one step using, for example, a spin coater before the wafer 20 is transported into the imprint device.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An imprint device that performs imprint processing on a processing substrate having a plurality of shot regions, which include a first shot region and a second shot region, the imprint device comprising:
a first template having a first pattern to be transferred to a resin material disposed on either the processing substrate or a dummy substrate; and
a control unit configured to perform:
first imprint processing in which the first template is pressed against an uncured first resin material disposed on one shot region among the plurality of shot regions to transfer the first pattern to the first resin material disposed on the one shot region, and
second imprint processing in which the first template is pressed against an uncured second resin material disposed on the dummy substrate,
wherein the control unit performs the second imprint processing after the first imprint processing performed on the first shot region and before the first imprint processing performed on the second shot region.

2. The imprint device according to claim 1, wherein
the first shot region is disposed at an outer periphery of the processing substrate and has a shot region size that is less than that of the second shot region, and
the control unit is configured to perform the first imprint processing on the first shot region and the second shot region in successive order.

3. The imprint device according to claim 1, further comprising:
a placing table on which the processing substrate is placed during the first imprint processing and on which the dummy substrate is placed during the second imprint processing,
wherein the control unit is further configured to control the placing table to be moved in position for the first imprint processing and the second imprint processing.

4. The imprint device according to claim 3, wherein
the processing substrate is a circular processing wafer and the dummy substrate is a circular dummy wafer.

5. The imprint device according to claim 3, wherein
the processing substrate is a circular processing wafer and the dummy substrate is a substrate having a size that is smaller than the processing substrate but greater than or equal to that of one shot region.

6. The imprint device according to claim 1, wherein the placing table includes
a first placing table on which the processing substrate is placed during the first imprint processing, and
a second placing table on which the dummy substrate is placed during the second imprint processing,
wherein the control unit is further configured to independently control the first placing table to be moved in position for the first imprint processing and the second placing table to be moved in position for the second imprint processing.

7. The imprint device according to claim 6, further comprising:
a second template having a second pattern to be transferred to a resin material disposed on either the processing substrate or the dummy substrate,
wherein the control unit is further configured to perform:
third imprint processing in which the second template is pressed against an uncured third resin material disposed on another shot region among the plurality of shot regions to transfer the second pattern to the third resin material disposed on the another shot region, and
fourth imprint processing in which the second template is pressed against an uncured fourth resin material disposed on the dummy substrate, and
wherein the plurality of shot regions further includes a third shot region and a fourth shot region, and the control unit performs the fourth imprint processing after the third imprint processing performed on the third shot region and before the third imprint processing performed on the fourth shot region.

8. An imprint device that performs imprint processing on a processing substrate having a plurality of shot regions, the imprint device comprising:
a placing table on which the processing substrate is to be placed;
a template having a pattern to be transferred to an uncured resin material disposed on the processing substrate;
a light source that emits light for curing the uncured resin material; and
a light shielding plate that is disposed in an optical path of the light source, wherein the light shielding plate includes
a frame-shaped first light shielding plate that frames an opening having a shape similar to the shape of one shot region and through which the light emitted from the light source passes, and
a second light shielding plate that is movable relative to the frame-shaped first light shielding plate to partially block the light passing through the opening.

9. The imprint device according to claim 8, wherein
the second light shielding plate is rotatable around the opening and movable in a linear direction toward a center of the opening to partially block the light passing through the opening.

10. The imprint device according to claim 9, further comprising a control unit configured to control the second light shielding plate during the imprint processing, wherein
the plurality of shot regions includes a first shot region and a second shot region, and
the control unit controls the second light shielding plate to be completely retracted from the opening when the imprint processing on the second shot region is performed, and to partially block the opening when the imprint processing on the first shot region is performed.

11. The imprint device according to claim 10, wherein the first shot region is disposed at an outer periphery of the processing substrate and has a shot region size that is less than that of the second shot region.

12. An imprint method performed by an imprint device that performs imprint processing on a processing substrate having a plurality of shot regions, which include a first shot region and a second shot region, the imprint method comprising:
first imprint processing in which a first template is pressed against an uncured first resin material disposed on one shot region among the plurality of shot regions of the processing substrate to transfer a pattern of the first template to the first resin material; and
second imprint processing in which the first template is pressed against an uncured second resin material that is disposed on a dummy substrate to transfer the pattern to the second resin material,
wherein the second imprint processing is performed after the first imprint processing performed on the first shot region and before the first imprint processing performed on the second shot region.

13. The imprint method according to claim 12, wherein
the first shot region is disposed at an outer periphery of the processing substrate and has a shot region size that is less than that of the second shot region, and
the first imprint processing on the first shot region and the second shot region are performed in successive order.

14. The imprint method according to claim 13, wherein
the first imprint processing on the first shot region is performed during the second imprint processing, and
the second imprint processing is performed during the first imprint processing on the second shot region.

15. The imprint method according to claim 14, wherein
the imprint device includes a first placing table on which the processing substrate is placed, a second placing table on which the dummy substrate is placed, and a dropping device that drops an uncured resin material onto the processing substrate or the dummy substrate, and said method further comprises:
moving the first placing table below the first template, while moving the second placing table below the dropping device, and performing, in parallel, the first imprint processing on the first shot region and dropping of the uncured second resin material onto the dummy substrate by the dropping device, and then
after completion of the first imprint processing on the first shot region, moving the second placing table below the first template, while moving the first placing table below the dropping device, and then performing, in parallel, the second imprint processing and dropping of an uncured first resin material onto the second shot region by the dropping device.

16. The imprint method according to claim 15, wherein
the imprint device further includes a second template having a second pattern to be transferred to a resin material disposed on either the processing substrate or the dummy substrate, and said method further comprises:
third imprint processing in which the second template is pressed against an uncured third resin material disposed on another shot region among the plurality of shot regions to transfer the second pattern to the third resin material disposed on the another shot region, and
fourth imprint processing in which the second template is pressed against an uncured fourth resin material disposed on the dummy substrate, and
wherein the plurality of shot regions further includes a third shot region and a fourth shot region, and the fourth imprint processing is performed after the third imprint processing performed on the third shot region and before the third imprint processing performed on the fourth shot region.

17. The imprint method according to claim 16, further comprising:
after the first imprint processing on the first shot region is performed, moving the second placing table below the first template, while moving the first placing table below the second template, and then performing the second imprint processing on the dummy substrate in parallel with the third imprint processing on the second shot region.

18. The imprint method according to claim 12, wherein
the plurality of shot regions further includes a third shot region, and the first imprint processing on the third shot region is performed and then in successive order the first imprint processing on the first shot region is performed before any other first or second imprint processing is performed, and
each of the third shot region and the first shot region is disposed at an outer periphery of the processing substrate and has a shot region size that is less than that of the second shot region.

19. The imprint method according to claim 18, wherein the shot region size of the third shot region is greater than that of the first shot region.

20. The imprint method according to claim 19, wherein the first imprint processing on the third shot region, the first imprint processing on the first shot region, and the second imprint processing are performed in successive order.
